(19) United States
(12) Patent Application Publication
(10) Pub. No.: US 2024/0288507 A1
(43) Pub. Date: Aug. 29, 2024

(54) Methods, Systems, and Devices for Wireless Power Modules

(71) Applicant: Alliance for Sustainable Energy, LLC, Golden, CO (US)

(72) Inventors: Faisal Habib KHAN, Littleton, CO (US); MD Sarwar ISLAM, Lakewood, CO (US); Joshua John MAJOR, Kittredge, CO (US); Shuofeng ZHAO, Golden, CO (US)

(21) Appl. No.: 18/585,497

(22) Filed: Feb. 23, 2024

Related U.S. Application Data
(60) Provisional application No. 63/486,703, filed on Feb. 24, 2023.
(60) Provisional application No. 63/609,974, filed on Dec. 14, 2023.

(51) Int. Cl. G01R 31/40; G01R 31/26; G01R 31/327; H02J 50/80; H02M 3/158; H03K 17/687

(52) U.S. Cl. CPC G01R 31/40; G01R 31/327; H02J 50/80; H02M 3/158; H03K 17/687; G01R 31/2621

(57) ABSTRACT

A power module that receives a control signal over a wireless connection with the power module using the control signal to generate a driving signal that drives one or more power switches is described. An aging detection feature for a power module is also described. The aging detection feature may employ a level searching circuit and a pulse counting technique that provides information about the state of health of one or more power switches. The information may include estimated values for on-state resistance and/or threshold voltage of one or more power switches.

### CROSS REFERENCE TO RELATED APPLICATIONS

This application claims the benefit of U.S. Provisional Patent Application No. 63/486,703, filed on Feb. 24, 2023, and U.S. Provisional Patent Application No. 63/609,974, filed on Dec. 14, 2023, the entire contents of each of which are hereby incorporated by reference.

### CONTRACTUAL ORIGIN

This invention was made with United States government support under Contract No. DE-AC36-08GO28308 awarded by the U.S. Department of Energy. The United States government has certain rights in this invention.

### BACKGROUND

A half-bridge power module is an integral part of any high-power energy conversion system. In the modular multilevel converter, the power flow is mostly controlled by sub-modules consisting of the half- and/or full-bridge circuits. These medium-voltage power devices or sub-modules can withstand a high blocking voltage (e.g., up to approximately 15 kV for silicon carbide (SiC) metal oxide semiconductor field effect transistors (MOSFETs) and/or up to approximately 27 kV for SiC insulated gate bipolar transistors (IGBTs)) at pulse width modulation (PWM) frequency. The safe operation of these modules is maintained through isolated power supplies feeding the driver circuits, either through galvanic isolation or wireless power transfer (WPT) systems. In addition, high-voltage isolation is also needed to separate the high-voltage bus from the low-voltage signal bus intended for PWM and other control signals. While it has been shown that the commercially available gate drivers for SiC-based power devices possess a blocking voltage in the range of approximately 650 V to approximately 1700 V, there exist a very few commercially available gate drivers for 10 kV SiC MOSFETs; however, commercialization of these modules is not feasible due to disproportionate manufacturing costs and design complexities. Thus, there remains a need for a universal architecture for medium-voltage power modules that could be used with both SiC and GaN devices for high-voltage applications and may be stretched to accommodate future Ga₂O₃ MOSFETs.

### BRIEF DESCRIPTION OF THE DRAWINGS

Some embodiments of the present disclosure are illustrated in the referenced figures of the drawings. It is intended that the embodiments and figures disclosed herein are to be considered illustrative rather than limiting.

FIG. 1 illustrates a block diagram of a system including a power module according to some aspects of the present disclosure.

FIG. 2 illustrates an example power circuit according to some aspects of the present disclosure.

FIG. 3 illustrates two resonant paths during different phases of switching transients in a half-bridge which can be monitored using an aging detector of the present disclosure.

FIG. 4 illustrates an equivalent circuit model of the half-bridge resonant loops during switching transients which can be monitored using the aging detector of the present disclosure.

FIG. 5A illustrates numerical waveform of the first few resonant peaks of v_{gs} following turning on after dead time for a MOSFET to be monitored using the aging detector of the present disclosure.

FIG. 5B illustrates numerical waveform of the first few resonant peaks of v_{gs} following turning off at the beginning of dead time for a MOSFET to be monitored using the aging detector of the present disclosure.

FIG. 6A illustrates circuit simulation results of the resonant peaks differences of v_{gs} for a Vₜₕ of turn-on transient, zero DC bus voltage, according to some aspects of the present disclosure.

FIG. 6B illustrates circuit simulation results of the resonant peaks differences of v_{gs} for a Vₜₕ of turn-on transient, positive DC bus voltage, according to some aspects of the present disclosure.

FIG. 6C illustrates circuit simulation results of the resonant peaks differences of v_{gs} for a Vₜₕ of turn-off transient, zero DC bus voltage, according to some aspects of the present disclosure.

FIG. 6D illustrates circuit simulation results of the resonant peaks differences of v_{gs} for a Vₜₕ of turn-off transient, positive DC bus voltage, according to some aspects of the present disclosure.

FIG. 7A illustrates circuit simulation results of the resonant peaks differences of v_{gs} for R_{ds,on} for turn-on transient, zero DC bus voltage, according to some aspects of the present disclosure.

FIG. 7B illustrates circuit simulation results of the resonant peaks differences of v_{gs} for R_{ds,on} for turn-on transient, positive DC bus voltage, according to some aspects of the present disclosure.

FIG. 7C illustrates circuit simulation results of the resonant peaks differences of v_{gs} for R_{ds,on} for turn-off transient, zero DC bus voltage, according to some aspects of the present disclosure.

FIG. 7D illustrates circuit simulation results of the resonant peaks differences of v_{gs} for R_{ds,on} for turn-off transient, positive DC bus voltage, according to some aspects of the present disclosure.

FIG. 8A illustrates a level-searching circuit for v_{gs} peak detection (i.e., aging detection) according to some aspects of the present disclosure.

FIG. 8B illustrates the principle of operation for the level searching circuit for v_{gs} peak detection according to some aspects of the present disclosure.

FIG. 9A illustrates results from an aging detector for a Phase V sixpack (aged) according to some aspects of the present disclosure.

FIG. 9B illustrates results from an aging detector for a Phase W sixpack (new) according to some aspects of the present disclosure.

FIG. 9C illustrates results from an aging detector for a single TO-247 (aged) according to some aspects of the present disclosure.

FIG. 9D illustrates results from an aging detector for a single TO-247 (new) according to some aspects of the present disclosure.

FIGS. 10A-10D illustrate detection results for Vₜₕ change shown with scope measurements according to some aspects of the present disclosure.

FIGS. 10E-10H illustrate detection results for Vₜₕ change shown with pulse counts according to some aspects of the present disclosure.

FIGS. 11A-11D illustrate detection results for R_{ds,on} change shown with scope measurements according to some aspects of the present disclosure.

FIGS. 11E-11H illustrate detection results for R_{ds,on} change shown with pulse counts according to some aspects of the present disclosure.

FIG. 12 illustrates a method for operating a power module according to some aspects of the present disclosure.

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

As used herein, “gate driver” refers to an amplifier that receives a relatively low-power electrical pulse from a controller integrated circuit (IC) and produces a relatively high-power electrical pulse to drive the power switch(es) (e.g., power transistor(s)).

Aspects of the present disclosure are directed to a power module that receives a control signal over a wireless connection with the power module using the control signal to generate a driving signal that drives one or more power switches. Other aspects of the present disclosure are directed an aging detection feature for a power module. The aging detection feature may employ a level searching circuit and a pulse counting technique that provides information about the state of health of the one or more power switches. The information may include estimated values for on-state resistance and/or threshold voltage of the one or more power switches. These and other aspects of the present disclosure are described in more detail below with reference to the figures.

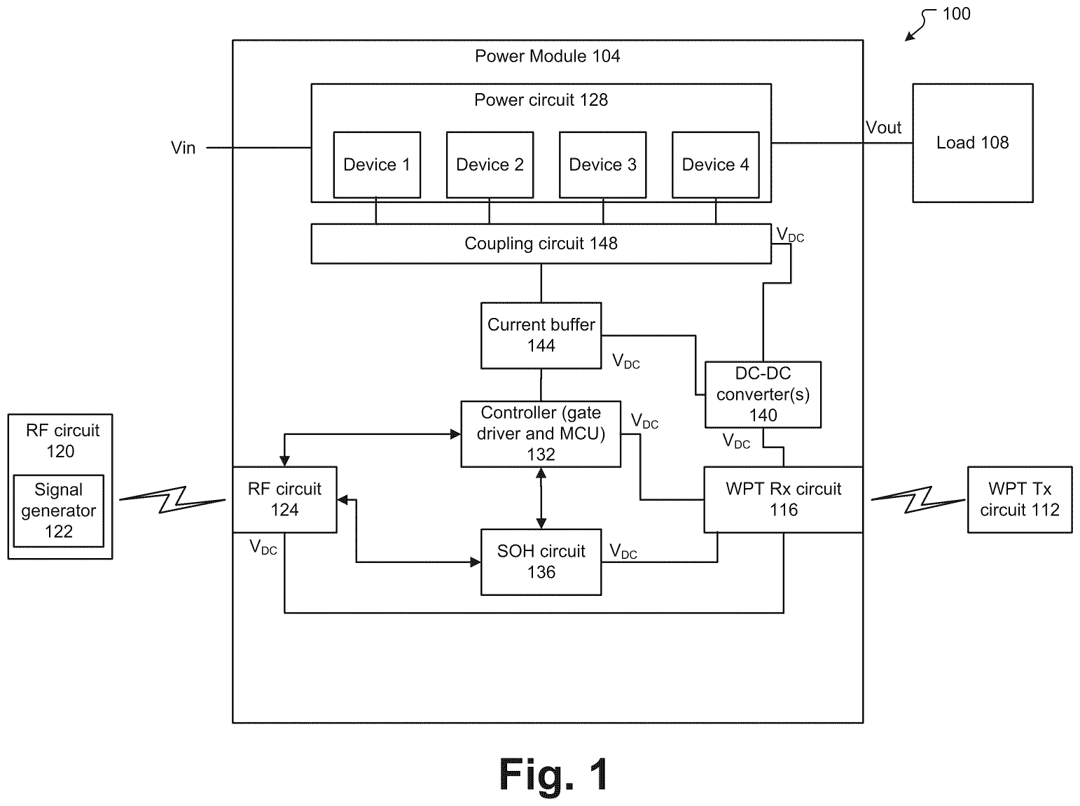

FIG. 1 illustrates a system 100 according to at least one aspect of the present disclosure. The system 100 includes a power module 104 that provides power to a load 108. The system 100 further comprises wireless interfaces with corresponding transmitters and/or receivers, embodied in FIG. 1 as Wireless Power Transfer (WPT) Tx and Rx circuits 112 and 116 and as radio frequency (RF) circuits 120 and 124. The WPT Tx and Rx circuits 112 and 116 comprise suitable circuitry for enabling wireless transfer of power to the power module 104. For example, the WPT Tx and Rx circuits 112 and 116 comprise inductors that create an inductive power transfer link. As may be appreciated, the WPT Tx circuit 112 may also comprise or be connected to a power source (e.g., an approximately 12V DC source) and switches that are controlled to generate the power signal for wireless transfer to the WPT Rx circuit 116. In one specific but non-limiting example, the WPT 112 and 116 circuits are capable of supplying approximately 1A of substantially steady-state current and approximately tens of amps of surge currents to drive the devices 1 to 4. This may minimize switching loss and potentially eliminate the use of additional DC-DC converters 140 needing high electrical insulation.

While the wireless interfaces 112 and 116 are used for wireless transfer of power, the RF circuits 120 and 124 are used for wireless communication. Thus, the RF circuits 120 and 124 comprise suitable hardware and/or software for enabling wireless communication. For example, the RF circuits 120 and 124 each include an antenna and circuitry for exchanging wireless signals according to one or more wireless protocols such as the IEEE 802.11 suite of protocols used for Wi-Fi, ultra wideband (UWB) protocols, BLUETOOTH protocols, and/or the like. According to aspects of the present disclosure, the RF circuit 120 may include or be connected to a signal generator, such as a signal generator 122 that generates a pulse width modulation (PWM) signal for wireless transmission to the RF circuit 124 which is then used to generate a drive signal for driving devices 1 to 4.

Still with reference to FIG. 1, the system 100 includes a power circuit 128 with a number of devices (e.g., devices 1 to 4) that generate an output voltage Vout (based on an input voltage Vin provided by an external source and drive signals from a controller 132) for powering a load 108. As discussed in more detail below, the devices 1 to 4 may correspond to power switches or power transistors, such as SiC MOSFETs, SiC IGBTs, GaN MOSFETs, Ga₂O₃ MOSFETs, and/or the like, which are driven according to drive signals from a controller 132 that includes a gate driver and suitable hardware and/or software for computing tasks, such as a digital signal processor (DSP), a microcontroller (MCU), a field programmable gate array (FPGA), an application specific integrated circuit (ASIC), a general purpose processor executing instructions stored on an internal memory, and/or the like.

In some aspects of the present disclosure, the power module 104 further comprises a state of health (SOH) circuit 136 that aids collection of information indicative of the operational well-being of components within the power module 104. For example, as described in more detail below with reference to the remaining figures, the SOH circuit 136 comprises circuitry that enables the controller 132 to determine aging information for devices 1 to 4 that is then wirelessly communicated to an interested party through RF circuits 124 and 120.

The power module 104 may further comprise a power converter, such as DC-DC converter(s) 140, a buffer circuit, such as a current buffer 144, and a coupling circuit 148. As may be appreciated from the V_{DC} labels in FIG. 1, the WPT Rx circuit 116 may provide power V_{DC} to various elements of the power module 104, including the DC-DC converter 140. In some cases, the WPT Rx circuit 116 provides power directly to certain elements, such as the RF circuit 124, the controller 132, and the SOH circuit 136. For other elements of the power module 104, the voltage requirement for these elements may not match the voltage output by the WPT Rx circuit 116. In this case, the DC-DC converter 140 steps up or steps down the voltage from the WPT Rx circuit 116 to power these other elements—depicted in FIG. 1 as the current buffer 144 and the coupling circuit 148.

Here, it should be appreciated that certain elements of the power module 104 may be omitted depending on design. For example, the DC-DC converter(s) 140, the current buffer 144, and the coupling circuit 148 may be omitted or be unused if not required by design constraints of the system 100 (e.g., the current buffer 144 and coupling circuit 148 may be omitted for the half-bridge configuration discussed in more detail below). In addition, it should be appreciated that one or more components illustrated in FIG. 1 may be integrated with one or more other components in FIG. 1. For example, the RF circuit 124 may be integrated with the controller 132. In the example of FIG. 1, the controller 132 include a microcontroller (MCU) with an on-board Wi-Fi or UWB interface. The MCU may be programmed using Python, JAVA, or another coding language. The MCU 132 may have on-chip analog-to-digital converter (ADC) and/or on-chip digital-to-analog converter (DAC).

Although not explicitly shown, the illustrated components of the power module 104 may be mounted on or integrated with a printed circuit board (PCB) housed in a housing intended to protect the components from the external environment.

Still with reference to FIG. 1, an aspect of the present disclosure relates to a power module 104 capable of using wireless network protocols (e.g., wi-fi, ultrawide band (UWB), etc.) and which exploits wireless power transfer (WPT) to eliminate gate drive ancillary power supply issues, particularly at extremely high voltage levels (e.g., greater than approximately 20 kV) and the need to isolate the pulse width modulating (PWM) signal that drives power switches in the power circuit 128. In the present disclosure, the PWM signal for a power module 104 is transmitted to the power module 104 wirelessly, such as over UWB or Wi-Fi, which provides the flexibility to isolate (in some embodiments completely) the power module 104 from the low-voltage bus, thus making it an essentially two-terminal device with a terminal for Vin and a terminal for Vout. Using the PWM over wireless communication, the WPT-powered controller 132 with a gate driver and the onboard SOH circuit 136 make the power module 104 a “smart” module and close in performance to a two-terminal device (i.e., an ideal switch) with a terminal for Vin and a terminal for Vout. In some embodiments, the WPT Tx and Rx circuits 112 and 116 support up to approximately 15 W (or approximately 12 V×approximately 1.25 A) power transfer. The WPT Tx and Rx circuits 112 and 116 may be WPC 1.2.2/Qi compliant.

In some embodiments, the wireless-enabled power module 104 has only two electrically accessible terminals as Vin and Vout, and the PWM signal (incoming) and the SOH information and other feedback (outgoing) are communicated wirelessly via RF circuit 124. This design may enable a weather-proof solution with adequate electromagnetic interference suppression ability. By enabling remote monitoring and control, the power module 104 may be used in an artificial intelligence-enable system (or other automated system) and/or with power converters used in extreme weather conditions such as in geothermal, aerospace, and mining applications. The wireless-enabled power module 104 may also be applied to power distribution systems and may function as a major building block in sold-state transformers and flexible alternating current (AC) transmission systems.

Powering the wireless-enabled power module 104 with WPT enables a system that can run under harsh conditions where low voltage ancillary supply is traditionally challenging. The wireless communication capabilities of the power module 104 may enable the PWM signal to be changed (e.g., through feedback to the signal generator 122) and various system parameters (e.g., temperature, voltage, current, and/or fault conditions) may be monitored remotely.

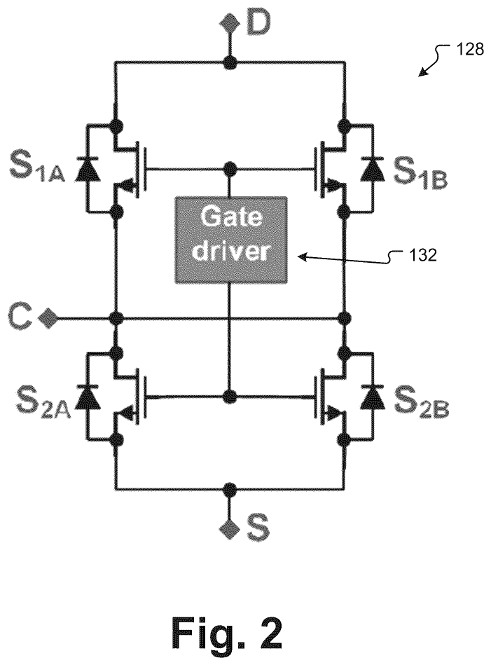

FIG. 2 shows a gate driver, which may be part of or at least connected to controller 132, and a half-bridge circuit with four (4) power switches, such as MOSFETs S1a to S2b, with two (2) parallel MOSFETs in the switch position. The half-bridge circuit may correspond to the power circuit 128 in FIG. 1 with each power switch S1a to S2b corresponding to one of the illustrated devices 1 to 4. In some embodiments, the gate driver is a dual channel isolated gate driver with approximately 10 A peak current per channel. The gate driver may have on-board approximately 2 W isolated power supplies and have the primary overvoltage lockout (OVLO) and undervoltage lockout (UVLO) with hysteresis. The gate driver may also have on-board overcurrent, shoot-through, and reverse polarity protection circuits. In the example of FIG. 2, power switches S1a to S2b are SiC devices rated at approximately 600 V and approximately 118 A; therefore, this half-bridge module was rated at approximately 600 V and approximately 236 A.

Although not explicitly shown, the power module 104 may have various cooling structures, such as water-ethylene glycol jet impingement thermal management system designed to cool the half-bridge circuit 128. In some examples, the power module 104 includes several mechanical parts such as a baseplate to accommodate the devices, a thermally conductive layer that provides voltage isolation, a heat exchanger unit, and the liquid cooling arrangement, among other things.

Tests for the configuration illustrated in FIG. 2 and described above will now be discussed. Here, testing was performed with only one device per switch and limiting the current to approximately 100 A. The power module 104 was tested using a power device analyzer to ensure proper device functionality. The first test performed was the gate threshold voltage (V_{TH}) measurements using the V_{GS}=V_{DS} settings on the power device analyzer. The MOSFET datasheet for the power switches showed a V_{TH} of between approximately 2.7 V and approximately 5.6 V, and the test results showed a V_{TH} of approximately 4.7 V and approximately 4.72 V at approximately 100 μA for the upper and lower switch, respectively. The second test performed was the R_{DS(ON)} measurements where V_{GS} was maintained at approximately 18 V. The datasheet values for R_{DS(ON)} showed between approximately 17 mΩ and approximately 21.3 mΩ at approximately 25° C. and an I_{D} of approximately 47 A. The results from the power device analyzer showed an R_{DS(ON)} of approximately 27.54 mΩ and approximately 27.72 mΩ for the upper and lower switch, respectively. Due to the desire for higher amperage, the test was performed up to an I_{D} of approximately 100 A. The results came to be approximately 29.72 mΩ and approximately 30.16 mΩ for the upper and lower switch, respectively.

In operation, the signal generator 122 generates a PWM signal that is sent wirelessly by the RF circuit 120 to the RF circuit 124 which passes a corresponding signal to the controller 132. The gate driver of the controller 132, in turn, generates an amplified PWM signal based on the signal received from the RF circuit 124. The amplified PWM signal output by the gate driver drives the power switches shown in FIG. 2. In some embodiments, the PWM signal generated by the signal generator 122 has one or more signal characteristics that are carried through to the output of the gate driver. For example, the signal generator 122 may generate a PWM signal having a frequency and/or duty ratio that is the same as the frequency and/or duty ratio of the PWM signal output by the gate driver. In other embodiments, the signal generator 122 generates a signal that carries information indicative of the frequency and/or duty ratio intended for the PWM signal output by the gate driver. In this case, the MCU of the controller 132 may extract the frequency and/or duty ratio from the wirelessly received signal and output a corresponding PWM signal to the gate driver.

Notably, the controller 132 may gather operational feedback from the load 108 and send the feedback wirelessly back to signal generator 122, which the signal generator 122 (e.g., a proportional integral (PI) controller of the signal generator 122) uses to modify the frequency and/or duty cycle of the signal sent to the power module 104, thereby enabling adjustments to be made to the PWM signal output by the gate driver. Such feedback may comprise voltage and/or current consumption by the load 108 as measured at the load 108.

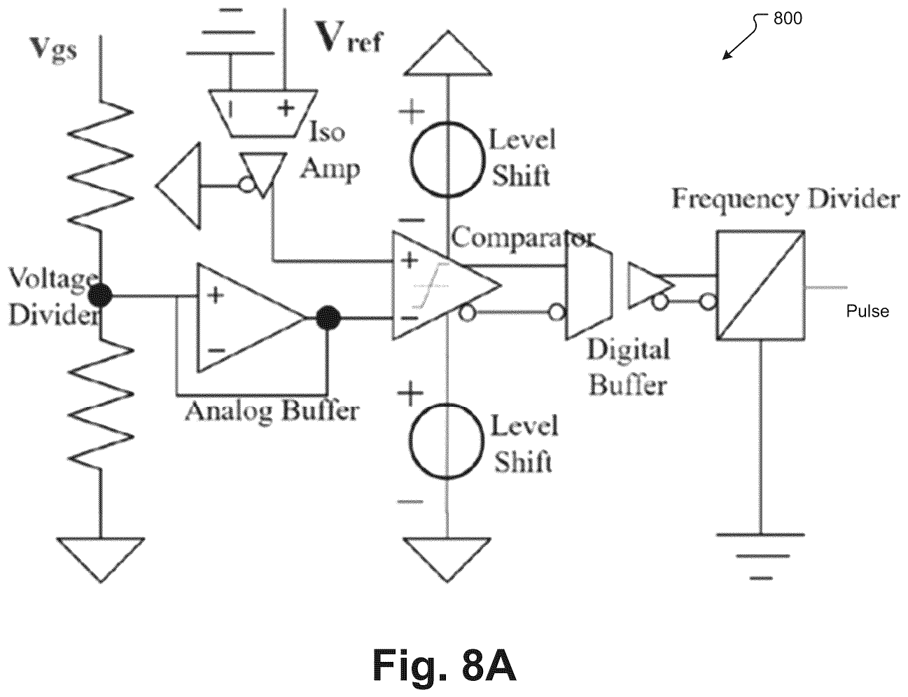

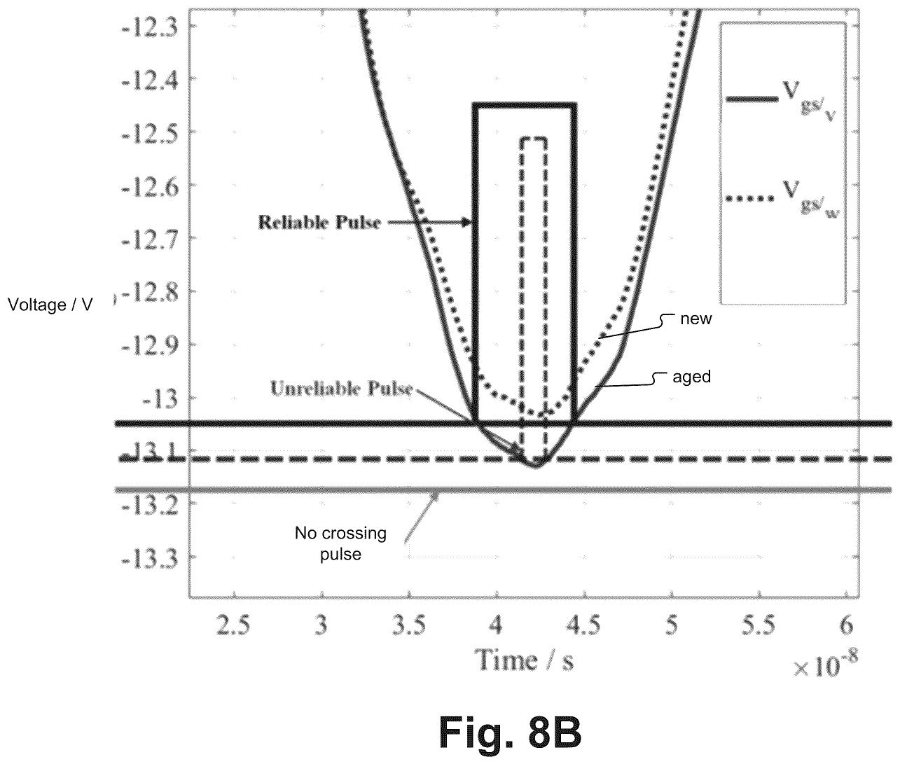

At least one aspect of the present disclosure to an aging detector for a power transistor, such as a silicon carbide (SiC) power MOSFET. The aging detector of the present disclosure leverages the resonant peak values of gate-source voltage at different instants during the switching transients to decode the change of multiple aging indicators, such as the increases of on-state resistance and threshold voltage. The aging detector may be fully integrated into the gate driver (and thus, integrated with the controller 132) without an additional connection to the power stage and is functional during normal power stage operation. The aging detector may comprise a level searching circuit (see FIG. 8A) coupled with processing functionality of an MCU of the controller 132 to interpret output of the level searching circuit.

The aging detector of the present disclosure may measure the gate voltage resonant peaks at multiple instants. In some embodiments, the aging detector can quantify the change in multiple aging indicators, such as on-state resistance and threshold voltage. In some embodiments, the aging detector may use the high device capacitance of SiC and its implication on gate voltage (v_{gs}) resonance during switching transients. The object of analysis in the discussion of the figures below relates to the upper switch (e.g., switch S1a in FIG. 2) of a half-bridge circuit, but the concepts are also applicable to the lower switch with certain changes in directions and initial conditions.

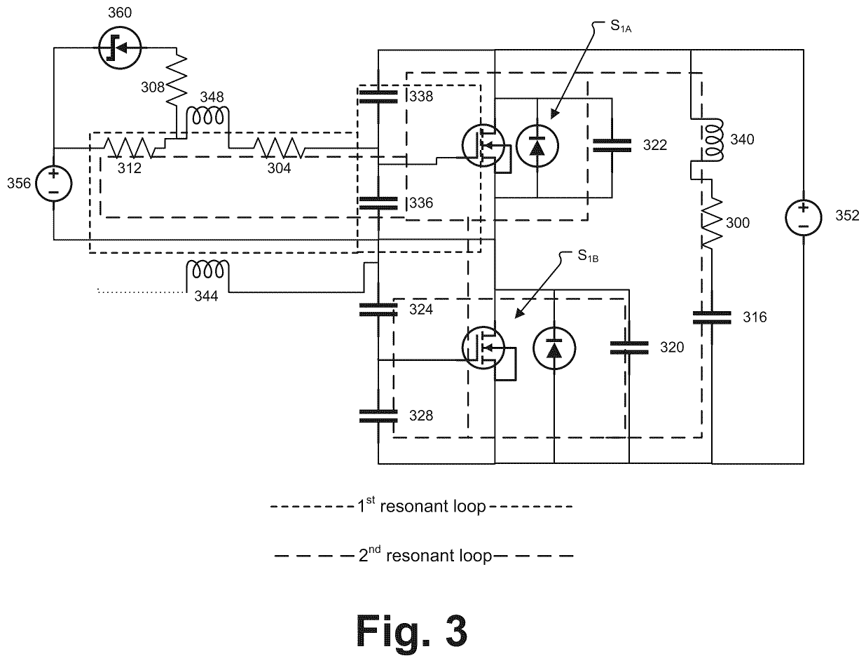

FIG. 3 illustrates two resonant paths during different phases of switching transients in a half-bridge which can be monitored using the aging detector of the present disclosure. An equivalent circuit model involving two switches S1a and S1b is shown in FIG. 3 and includes resistances 300, 304, 308, and 312, capacitances 316, 320, 322, 324, 328, 332, 336, 338, inductances 340, 344, and 348, voltages 352 and 356, and Zener diode 360. The two resonant loops shown in FIG. 3 are distinguished by the conduction state of the channel, which may be controlled by the gate voltage. Generally, when v_{gs} is less than vₜₕ, the channel is in an off state and the second resonant loop is engaged. Similarly, generally, when v_{gs} is greater than vₜₕ, the channel is in an on/conduction state, and the gate transient is approximately restrained within the first resonant loop.

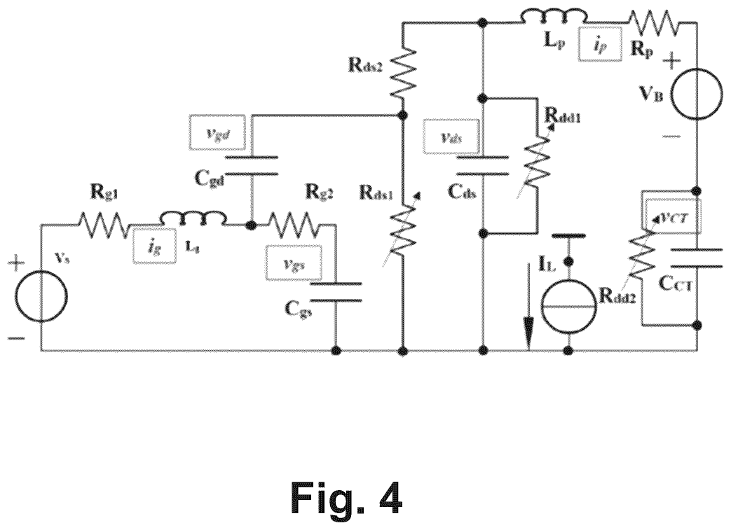

FIG. 4 illustrates an equivalent circuit model of the half-bridge resonant loops during switching transients which can be monitored using the aging detector of the present disclosure. The circuit model shown in FIG. 4 represents the MOSFET channel and body diode with voltage-controlled resistance and uses voltage-dependent functions to describe the gate and diode capacitors. In FIG. 4, R_{g1} and R_{g2} are gate driving loop resistances, C_{gs}, C_{gd}, and C_{ds} are gate-source capacitance, gate-drain capacitance, and drain-source capacitance, respectively. R_{ds1} and R_{ds2} are vgs-dependent and temperature-dependent channel resistances, respectively. R_{dd1} and R_{dd2} are v_{ds}-dependent equivalent body diode resistances for the respective MOSFETs. C_{CT} is the equivalent total capacitance of the complementary MOSFET when the channel is in an off state. L_{P} and R_{P} are the power loop parasitic inductance and resistance, respectively. V_{B} and I_{L} are the steady-state DC bus voltage and quasi-steady-state load current at the beginning of transients, respectively. i_{g}, v_{gs}, v_{gd}, v_{ds}, iₚ, and v_{ct} are gate driving current, gate-source voltage, gate-drain voltage, drain-source voltage, power loop current, and complementary switch voltage, respectfully. Variable-dependent parameters are C_{gs}, C_{gd}, C_{ds}, R_{dd1}, R_{dd2}, C_{CT}, R_{ds1}, and R_{ds2}. Meanwhile, select state variables for modeling are i_{g}, v_{gs}, v_{gd}, v_{ds}, iₚ, and v_{ct}.

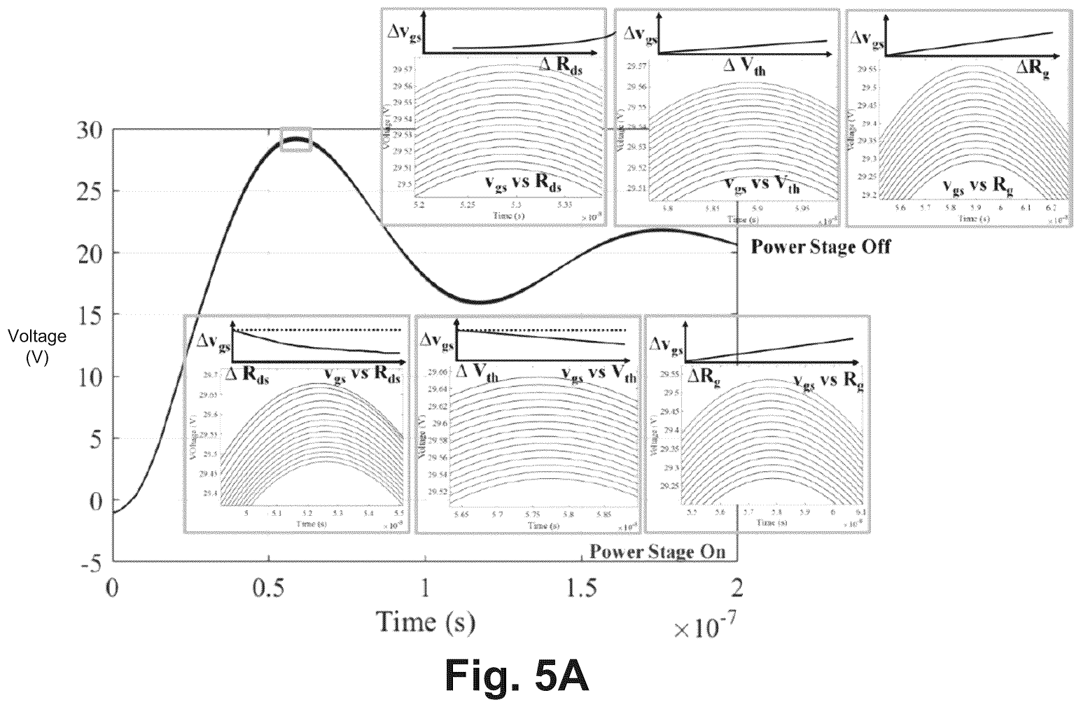

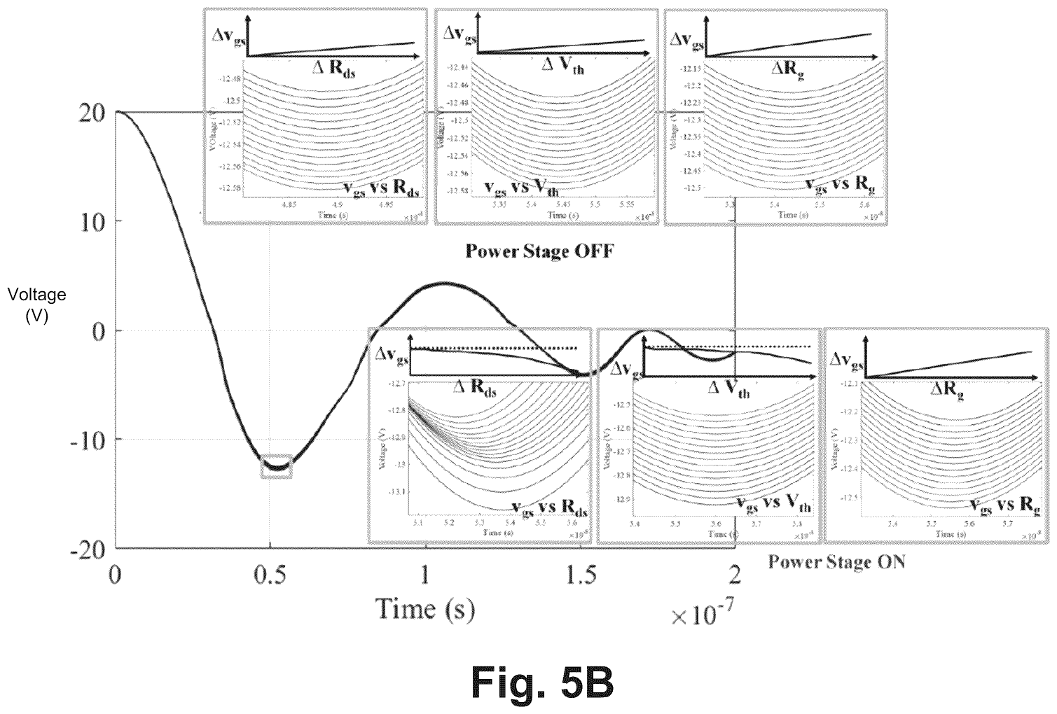

FIG. 5A illustrates numerical waveforms of the first few resonant peaks of v_{gs} following turning on after dead time for a MOSFET (e.g., a MOSFET in FIG. 2) to be monitored using the aging detector of the present disclosure. FIG. 5B illustrates numerical waveforms of the first few resonant peaks of v_{gs} following turning off at the beginning of dead time for a MOSFET to be monitored using the aging detector of the present disclosure.

Using approximate models for non-linear components yields the following model for the equivalent circuit for one switch in the form of system of ordinary differential equations (ODE) shown with equations (1) to (14) below.

$$TA = ( - \frac{{υ}_{ds ( t )}}{{R}_{ds 1} ( {υ}_{ds} ( t ) ) + {R}_{ds 2}} + \frac{{υ}_{gs} ( t ) - {υ}_{gd} ( t ) + {R}_{g 2} \cdot {i}_{g} \vert ( t )}{{R}_{ds 1} ( {υ}_{ds} ( t ) )} / ( 1 + \frac{{R}_{g 2}}{{R}_{ds 1} ( {υ}_{ds} ( t ) )} + \frac{{R}_{ds 1} ( {υ}_{ds} ( t ) )}{{R}_{ds 1} ( {υ}_{ds} ( t ) ) + {R}_{ds 2}} ) \qquad ( 1 )$$

$$\frac{{d υ}_{gs} ( t )}{dt} = \frac{1}{{C}_{gs} ( {υ}_{gs} ( t ) )} ( {i}_{g} ( t ) - TA ) \qquad ( 2 )$$

$$\frac{{d υ}_{gd} ( t )}{dt} = \frac{TA}{{C}_{gd} ( {υ}_{gd} ( t ) )} \qquad ( 3 )$$

$$\frac{{d υ}_{ds} ( t )}{dt} = \frac{1}{{C}_{ds} ( {υ}_{ds} ( t ) ) + {C}_{BD}} ( - \frac{{υ}_{ds} ( t )}{{R}_{ds 1} ( {υ}_{ds} ( t ) ) + {R}_{ds 2}} - {i}_{p} ( t ) - \frac{{υ}_{ds} ( t )}{{R}_{dd 1} ( {υ}_{ds} ( t ) )} + \frac{{R}_{ds 1} ( {υ}_{ds} ( t ) )}{{R}_{ds 1} ( {υ}_{ds} ( t ) ) + {R}_{ds 2}} TA ) \qquad ( 4 )$$

$$\frac{{d υ}_{CT} ( t )}{dt} = \frac{1}{{C}_{CT} ( {υ}_{CT} ( t ) )} ( {i}_{p} ( t ) - {i}_{L} - \frac{{υ}_{CT} ( t )}{{R}_{dd 2} ( {υ}_{CT} ( t ) )} ) \qquad ( 5 )$$

$$\frac{{di}_{g} ( t )}{dt} = \frac{1}{{L}_{g}} ( {V}_{S} - ( {R}_{g 1} + {R}_{g 2} ) {i}_{g} ( t ) - {υ}_{gs} ( t ) + {R}_{g 2} \cdot TA \qquad ( 6 )$$

$${C}_{gd} ( {υ}_{gd} ( t ) ) = {C}_{CD} ( ( 1 - \frac{1}{2} ( 1 - tanh ( {υ}_{gd} ( t ) ) ) {υ}_{gd} ( t ) ) \cdot ( 1 + {K}_{Cgd 1} \frac{1}{2} ( 1 + tanh ( - {K}_{Cgd 2} {υ}_{gd} ( t ) - {K}_{Cgd 3} ) ) ) ) \qquad ( 10 )$$

$${C}_{ds} ( {υ}_{ds} ( t ) ) = {C}_{DS} \cdot {K}_{Cds 1} \cdot {( 1 + \frac{1}{2} ( 1 + tanh ( {K}_{Cds 2} \cdot {υ}_{ds} ( t ) ) ) {υ}_{ds} ( t ) {K}_{Cds 3} \cdot {υ}_{ds} ( t ) )}^{- 0.5} \qquad ( 11 )$$

$${C}_{CT} ( {υ}_{CT} ( t ) ) = {C}_{ds} ( - {υ}_{CT} ( t ) ) + {C}_{BD} + 1 / ( \frac{1}{{C}_{gd} ( {υ}_{CT} ( t ) )} + \frac{1}{{C}_{GS}} ) \qquad ( 12 )$$

$${R}_{dd} ( {υ}_{dd} ) = {R}_{dd , on} \cdot \frac{1}{2} ( 1 - tanh ( {K}_{dd} ( {υ}_{dd} + {V}_{ddth} ) ) ) + {R}_{dd , off} \cdot \frac{1}{2} ( 1 + tanh ( {K}_{dd} ( {υ}_{dd} + {V}_{ddth} ) ) ) \qquad ( 13 )$$

$$\begin{matrix}{R}_{dd 1} ( {υ}_{ds} ( t ) ) = {R}_{dd} ( {υ}_{ds} ( t ) ) , \\ {R}_{dd 2} ( {υ}_{CT} ( t ) ) = {R}_{dd} ( - {υ}_{CT} ( t ) )\end{matrix} \qquad ( 14 )$$

All R_{sub} and C_{sub} represent baseline values for variable parameters and all K_{sub} symbols represent coefficients. Their values selected for simulations discussed herein are shown in Table 1.

TABLE I
COEFFICIENT VALUES IN SIMULATIONS

| Coefficient | Value | Unit |
|---|---|---|
| C_{GS} | 1440*10⁻¹² | F |
| C_{GD} | 680*10⁻¹² | F |
| C_{DS} | 50*10⁻¹² | F |
| C_{BD} | 460*10⁻¹² | F |
| R_{g1} | 3.8 | Ω |
| R_{g2} | 1*10⁻³ | Ω |
| R_{dd, on} | 25*10⁻³ | Ω |
| R_{dd, off} | 1*10⁹ | Ω |
| Rₚ | 90*10⁻³ | Ω |
| L_{g} | 125*10⁻⁹ | H |
| Lₚ | 60*10⁻⁹ | H |
| K_{Rds1} | 84*10⁻³ | none |
| K_{Rds2} | 0.3855 | none |
| K_{Rds3} | 2.05 | none |
| K [symbol] _{Cg} [symbol] | 720*10⁻¹² | none |
| K_{Cgsth} | 2.0 | none |
| V_{Cgsth1} | −5.0 | V |
| V_{Cgsth2} | 0 | V |
| K_{Cgd1} | 18.096 | none |
| K_{Cgd2} | 0.2678 | none |
| K_{Cgd3} | 7.5277 | none |
| K_{Cds1} | 50 | none |
| K_{Cds2} | 0.5127 | none |
| K_{Cds3} | 100 | none |
| K_{dd} | 50 | none |
| V_{dd} [symbol] | 3.5 | V |

[symbol]

indicates data missing or illegible when filed

Using numerical solvers for this model, and taking the parameter values listed above, knowledge of the behavior of the subject switch device (Sla) can be obtained for the time shortly after the switching.

The implications of the changes of channel threshold voltage Vth and channel on-state resistance R_{ds,on}, which are two of the most reliable and commonly referred aging indicators of SiC power MOSFETs, on the v_{gs} waveform were investigated. In particular, the corresponding change of the resonant peak values are of interest because the different parameter changes have their own characteristics, reflected in the different sensitivity patterns for v_{gs}. Therefore, it is possible to establish a database of impacts of these indicator value changes for almost any power module with known parameters. Subsequently, by combining the measurement results of v_{gs} peaks at different instants (turning on/off) in different conditions (power stage on/off), a multidimensional dataset is formed that can be used to pinpoint and quantify the change of a particular aging indicator (vₜₕ or/and R_{ds,on}) values using the database.

Simulation using the values in Table 1 reveals a general pattern. When the DC bus has approximately zero voltage, the v_{gs} peaks diminish in amplitude with the increase of Vₜₕ or R_{ds,on} for both turn-on and turn-off transients. When the DC bus has a positive voltage, the v_{gs} peaks augment in amplitude with the increase in Vth or R_{ds,on} for both turn-on and turn-off transients. The rate of change of v_{gs} peak amplitudes are unique in different scenarios. Basically, the rate of change is higher with positive DC bus voltage, higher for negative peaks (nadirs) than positive peaks, and the rate difference between zero DC bus voltage and positive voltage is greater for changed R_{ds,on} scenarios. The darker traces in FIGS. 5A and 5B correspond to larger amounts of change in respective parameter values. The total increase of R_{ds,on}, Vₜₕ, and R_{g} corresponding to the respective spans are 28 mΩ, 1.4 V, and 140 mΩ, respectively, with even intervals.

FIGS. 5A and 5B show the role of gate resistance R_{g} change. Conventionally, R_{g} is not an effective aging indicator. But this analysis reveals that the impact of R_{g} on v_{gs} peak values is significant, making it a potential disturbance to evaluating the real indicator value change. The pattern of R_{g}'s impact is distinct (as shown in FIGS. 5A and 5B), where the increase of R_{g} leads to diminished peaks (which is intuitive because it is a direct damper in the gate loop) and where the increases of R_{ds,on} and Vₜₕ may lead to diminished or augmented peaks based on conditions. This distinct pattern enables one to separate out the contribution of R_{g} change (if there is any), which allows the rejection of disturbance caused by R_{g}.

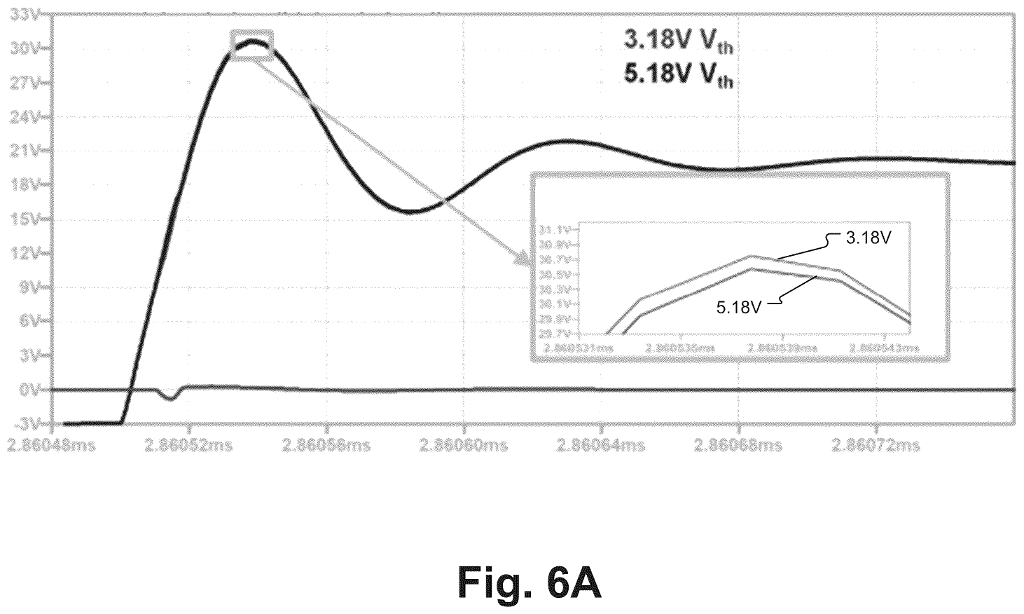

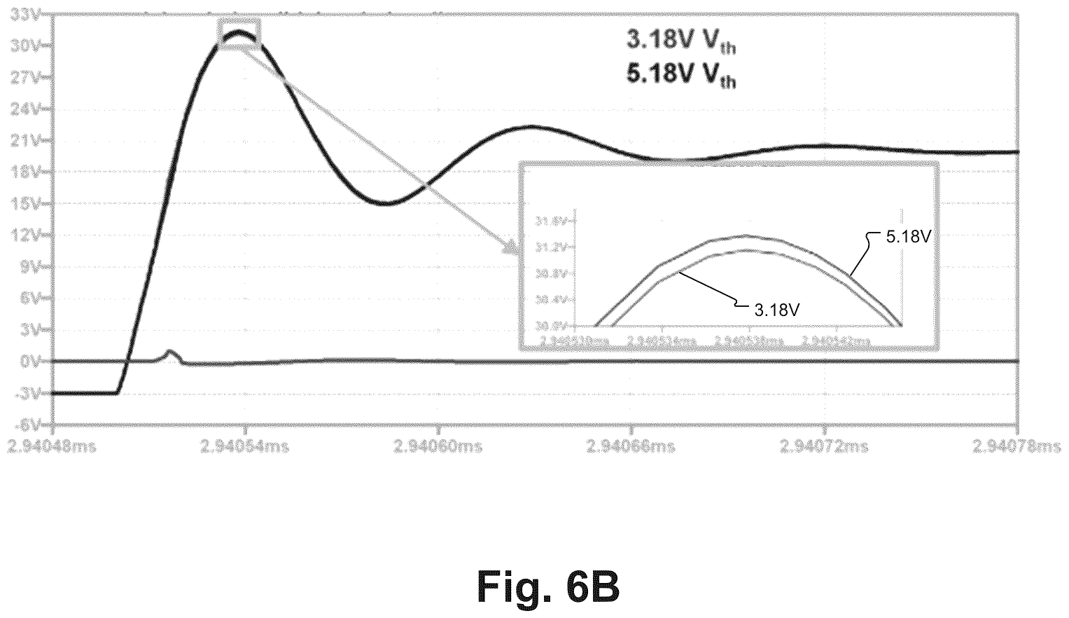

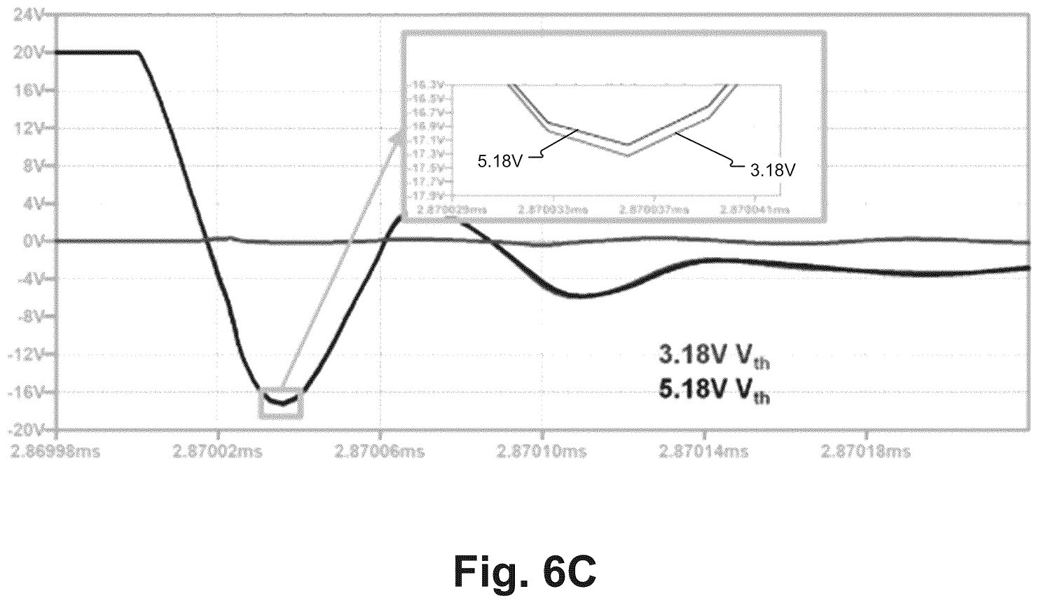

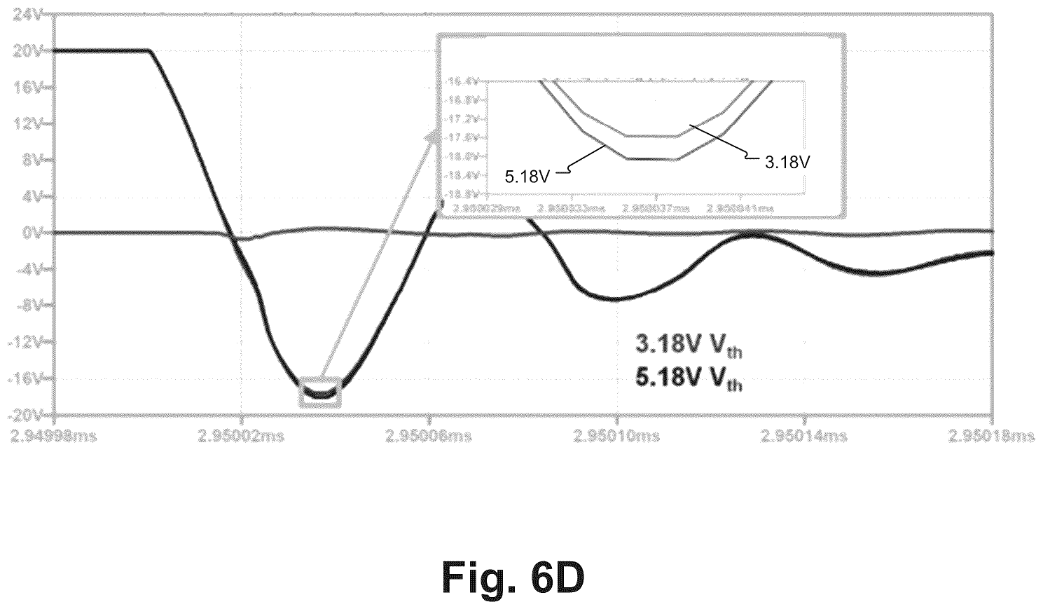

FIGS. 6A to 6D illustrate circuit simulation results of the resonant peak differences of v_{gs} for different Vₜₕ (i.e., 3.18V and 5.18V). In particular, FIG. 6A illustrates circuit simulation results of the resonant peaks differences of v_{gs} for a Vₜₕ of turn-on transient, zero DC bus voltage, according to some aspects of the present disclosure. FIG. 6B illustrates circuit simulation results of the resonant peaks differences of v_{gs} for a Vₜₕ of turn-on transient, positive DC bus voltage, according to some aspects of the present disclosure. FIG. 6C illustrates circuit simulation results of the resonant peaks differences of v_{gs} for a Vₜₕ of turn-off transient, zero DC bus voltage, according to some aspects of the present disclosure. FIG. 6D illustrates circuit simulation results of the resonant peaks differences of v_{gs} for a Vₜₕ of turn-off transient, positive DC bus voltage, according to some aspects of the present disclosure. Circuit simulations were conducted using LT-spice to corroborate the numerical results, as shown in FIGS. 6A-6D. The simulations feature half-bridge synchronous buck converters with a SiC MOSFET device model developed from the Wolfspeed CMP2-1200-0080B factory SPICE model. The SPICE model was modified to produce the changes in Vₜₕ and R_{ds,on}. Key parameters and coefficients were the same as for the numerical analysis. The simulation results shown in FIGS. 6A-6D show a similar pattern to the numerical results.

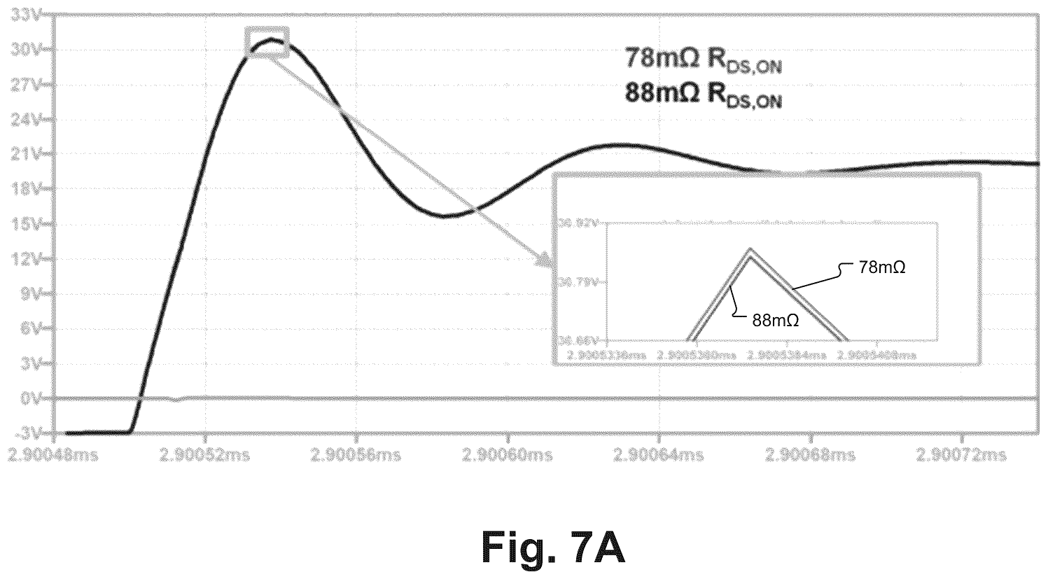

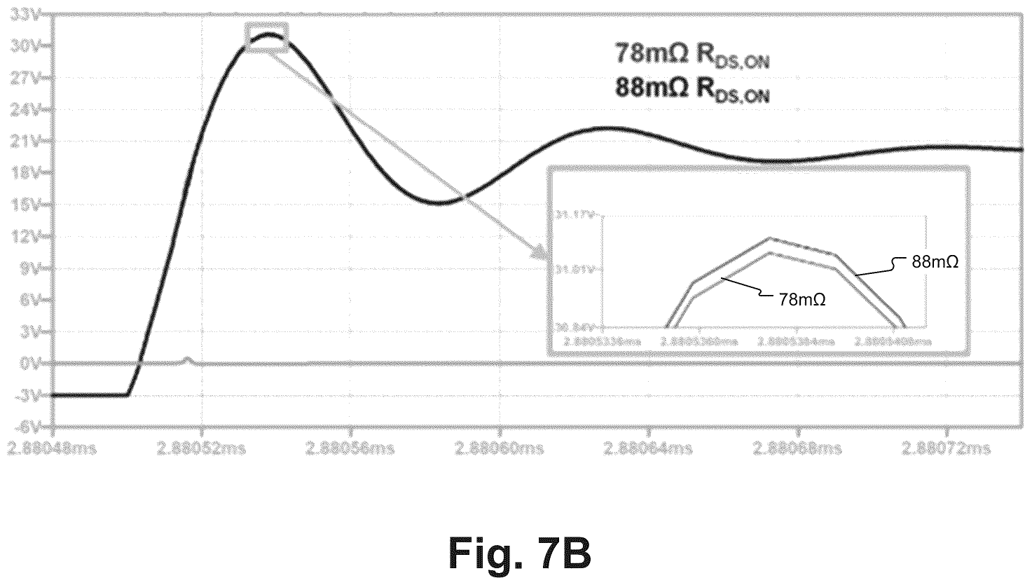

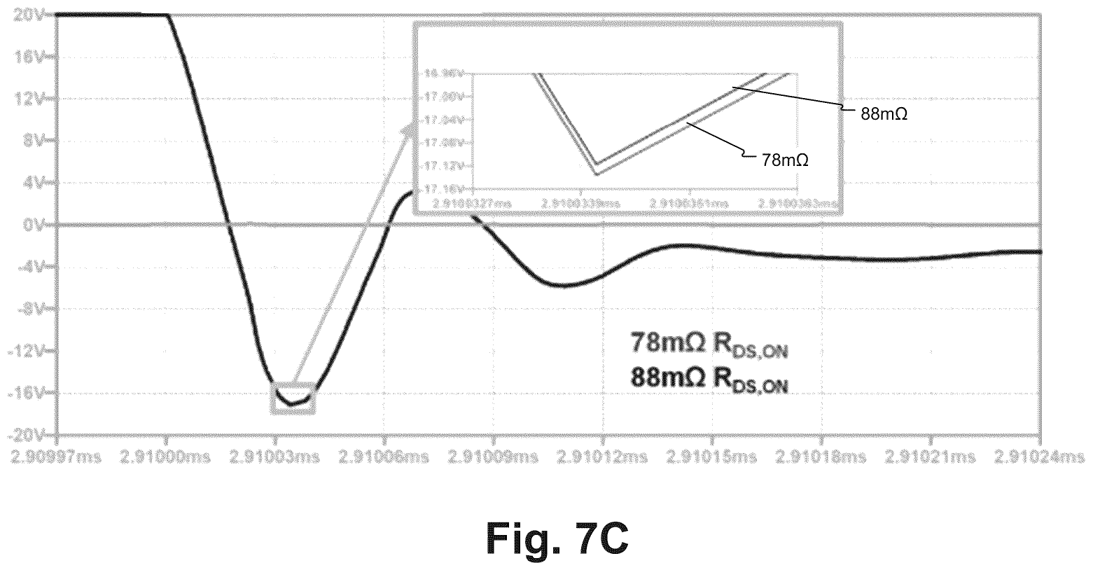

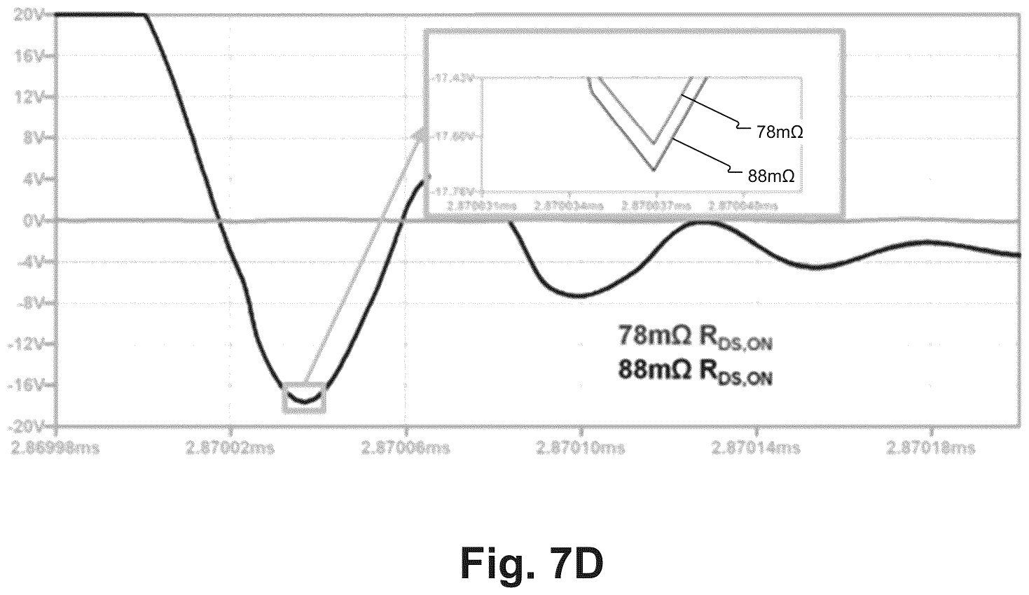

FIGS. 7A to 7D illustrate circuit simulation results that show the resonant peak differences of v_{gs} for different R_{ds,on}(approximately 78 mΩ and approximately 88 mΩ). In particular, FIG. 7A illustrates circuit simulation results of the resonant peaks differences of v_{gs} for R_{ds,on} for turn-on transient, zero DC bus voltage, according to some aspects of the present disclosure. FIG. 7B illustrates circuit simulation results of the resonant peaks differences of v_{gs} for R_{ds,on} for turn-on transient, positive DC bus voltage, according to some aspects of the present disclosure. FIG. 7C illustrates circuit simulation results of the resonant peaks differences of v_{gs} for R_{ds,on} for turn-off transient, zero DC bus voltage, according to some aspects of the present disclosure. FIG. 7D illustrates circuit simulation results of the resonant peaks differences of v_{gs} for R_{ds,on} for turn-off transient, positive DC bus voltage, according to some aspects of the present disclosure.

When the DC bus is not powered up and has approximately zero voltage, and during the turn-on transient, the device with higher Vₜₕ will conduct slower, resulting in a later transition from the second resonant loop to the first resonant loop. This means that the energy from the gate driver stored in the gate inductance will bleed into the second loop for a longer period for the higher Vₜₕ scenario, resulting in lower stored energy in the first loop and consequently lower v_{gs} peak when the gate capacitors obtain max charge. During the turn-off transient, the direction of change is in the opposite direction but with a similar idea—the device with higher vₜₕ will engage the second loop from the first loop earlier and thus for a longer period, losing more negative charge in the second loop, resulting consequently in a diminished v_{gs} negative peak when the gate capacitors hold max charge.

When the DC bus is powered on and maintains a positive voltage, and during the turn-on transient, the initial condition is quite different—because of the quasi-static current from the large output inductor flowing out of the drain, the body diode of the upper switch (Sa1) is in a forward conduction state after the beginning of the dead time and before channel turning on, clamping v_{ds} at the native forward voltage of the diode. After the turn-on transition begins and before the channel conducts, the gate driver and the gate inductance charges both c_{gs} and c_{gd} with low impedance in the respective paths—for c_{gd}, the path is through R_{ds2} to the clamped drain potential. During the channel turning-on period, the body diode exits the forward conduction state and releases the clamp on v_{ds}; meanwhile Vₜₕ has not yet reached the level for the channel to be fully conducting with low resistance. During this period, the second resonant loop is effectively engaged to the first loop, allowing energy exchange and the charging of c_{ds}. After the channel substantially fully conducts, the first loop is effectively decoupled from the second loop with lower channel resistance in the c_{gd} charging path. For the device with higher vₜₕ, the channel turning-on period occurs later in time, and the corresponding higher gate charging current compared to the device with lower vₜₕ during this time difference contributes to a higher energy stored in the first loop, consequently resulting in a higher v_{gs} peak when the gate capacitors obtain max charge.

During the turn-off transient for a positive DC bus voltage, the initial conditions and the corresponding analysis are different. After the transition begins and before the channel turns off, the gate driver and the gate inductance discharges both c_{gs} and c_{gd} through low impedance paths with no engaging to the second resonant loop. After v_{gs} drops below vₜₕ and the channel turns off, the second loop is engaged; but this time, the initial current flowing into the drain experiences a rapid decrease to wheel the current to the diode of the lower switch (Sa2). Consequently, the energy stored in the power loop parasitic inductance releases and becomes an extra energy source to reverse charge the gate capacitors, effectively resulting in a higher discharge current than before the channel turns off. For the device with higher vₜₕ, this higher discharge current period occurs earlier, and the time difference compared to a lower vₜₕ device and its corresponding gate current difference contributes to more charge moved from the first loop for the higher vₜₕ device, consequently resulting in an augmented v_{gs} negative peak when the gate capacitors obtain max negative charge.

The device with higher R_{ds,on} generally shows patterns of v_{gs} peak changes similar to those with higher vₜₕ in such a way that a higher R_{ds,on} makes the conducting channel resistance higher for the same vₜₕ, or alternatively, needs a higher v_{gs} to reach the same resistance, which apparently has a higher vₜₕ. However, differences for higher vₜₕ still exist, especially when significant conducting time periods occur during the transients before the v_{gs} peak occurs. For example, in the analysis for the turn-off transient for a positive DC bus voltage, the conducting channel is in the path of gate capacitor discharge before the v_{gs} negative peaks occur, therefore resulting in difference patterns of v_{gs} change compared to the various vₜₕ scenarios.

FIG. 8A illustrates a level-searching circuit 800 used for v_{gs} peak detection according to some aspects of the present disclosure. The circuit 800 may be included as part of the state of health (SOH) circuit 136. Meanwhile, FIG. 8B illustrates the principle of operation for the circuit 800 according to some aspects of the present disclosure.

The feasibility of leveraging the analysis described herein for practical Vₜₕ and R_{ds,on} detection relies on generating the resonant condition. From FIGS. 3-7D, one can find that the significant v_{gs} oscillations come from a relatively large gate driving loop inductance, which is not desirable for practical operation of the switch. Nevertheless, the zero DC bus voltage condition and positive DC bus near-zero load condition described above can be realized by incorporating small inductors to the gate driving loop and creating no load switching with the DC bus on. These added elements can be bypassed after the potential v_{gs} logging is finished. In such a way, normal operations are not affected and the in-situ diagnostics become possible. Stated another way, the power module 104 may operate in one of two modes—a diagnostic mode during which aging information about the power switches is collected and a normal operation mode during which the power module 104 powers a load 108. Selection of a particular mode may occur in response to user input that calls for the controller 132 to operate in either mode. The mode may also be selected automatically, such as upon elapse of a timer tracked by the controller 132, or in response to a period of load inactivity.

The combination of v_{gs} peak values is highly informative, but the differences are nuanced and the time window to acquire the information is short. The level-searching circuit 800 described herein is able to quantify the v_{gs} peak values under these conditions. FIG. 8B shows Vgs peak values for aged and new power switches to illustrate what are considered as a reliable and unreliable pulses output from the circuit 800. As shown in FIG. 8A, the circuit 800 includes a voltage divider circuit that receives v_{gs}, an isolation amplifier that receives Vref, an analog buffer that buffers output of the voltage divider, a comparator with level shifting capability that compares output of the isolation amplifier and output of the analog buffer, a digital buffer that buffers output of the comparator, and a frequency divider circuit connected in the illustrated configuration.

With reference to FIG. 8A, an adjustable voltage reference Vref is generated externally, such as by the controller 132. The controller 132 may gradually lift (increase) the reference voltage Vref with high resolution from an initial low value. As shown in FIG. 8, the reference voltage Vref and the conditioned v_{gs} values are handled by the illustrated comparator such that when the reference voltage Vref reaches the negative v_{gs} peak, a pulse “Pulse” is generated and output by the frequency divider. The pulse may finally be picked up or detected (e.g., counted) by the controller 132 to quantify the v_{gs} peak value and act as an aging detector. For positive peaks during turning on, the approach is the same (or similar) but in the reverse direction.

A useful feature of the pulse capturing detection design of the aging detector of the present disclosure is the concept's averaging capability to minimize the impact of uncertainties such as random noise. For example, the controller 132 may average the number of pulses for each reference voltage value on an approximately 1 second interval, and the average number of pulses per second is recorded for approximately 1 minute or approximately 60 times before the reference voltage Vref changes (i.e., is increased) by another notch. In this way, the peak voltage v_{gs} can be determined by finding the reference voltage Vref whose pulse number substantially jumps from zero to a positive value.

Testing for the illustrated circuit 800 will now be described. A prototype detection board (i.e., an aging detector) was developed and fabricated based on the concepts shown in FIGS. 8A and 8B. The board-generated detection pulses were picked up by a QEP module on a TI TMS320F28377D development board, and the pulse counts were delivered via SCI communication to the data acquisition (DAQ) laptop on an approximately 1 second basis.

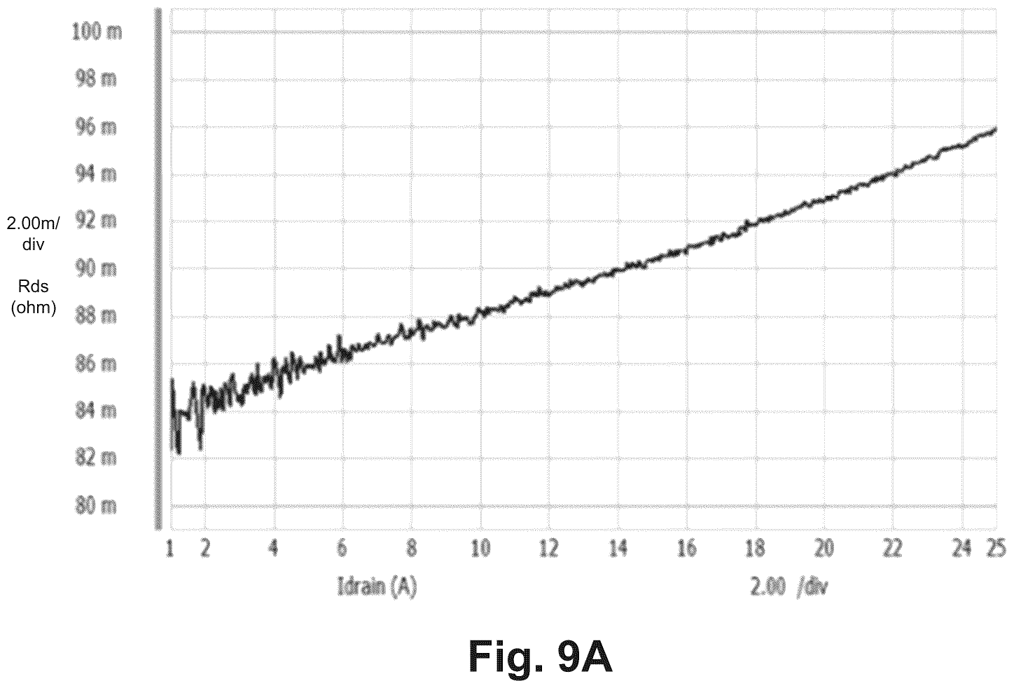

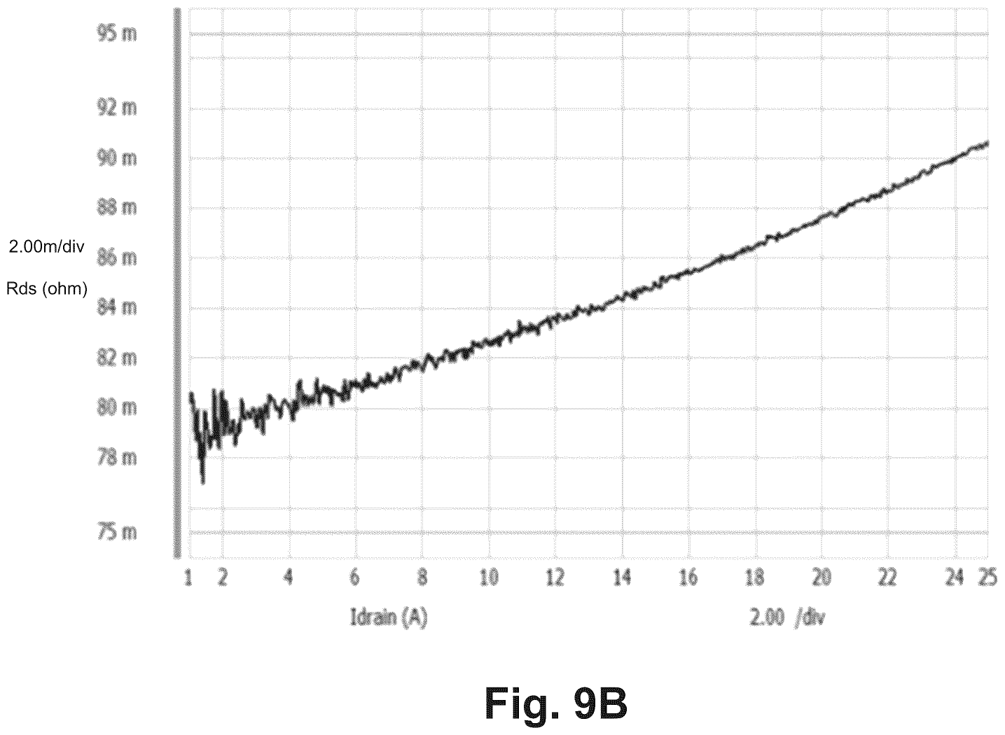

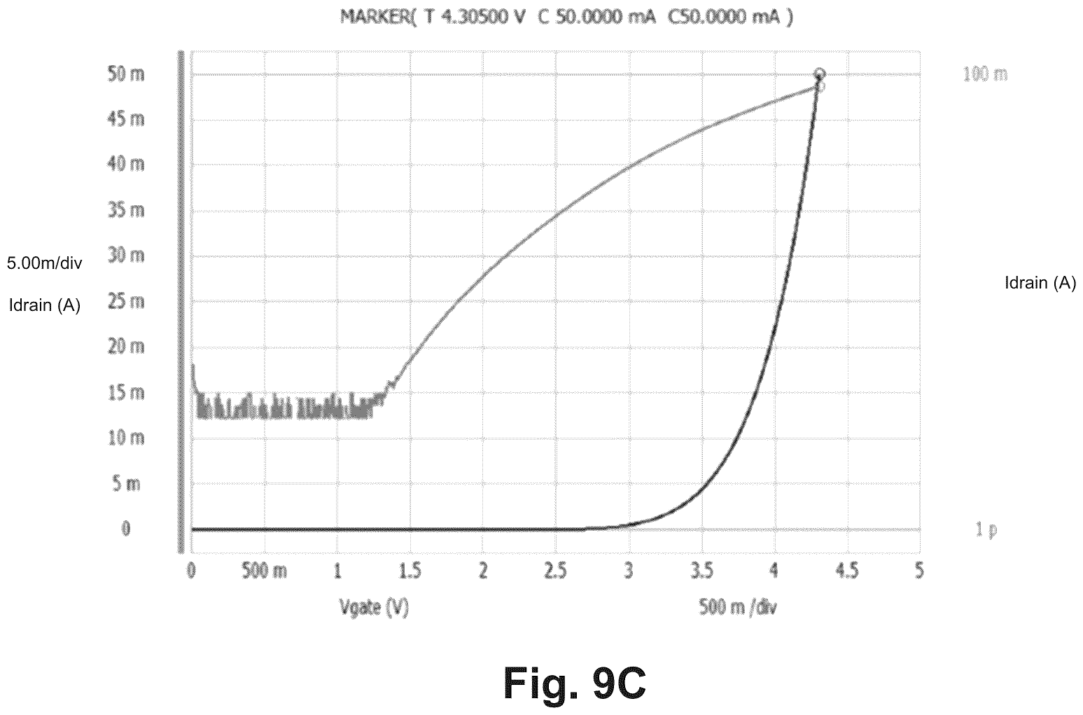

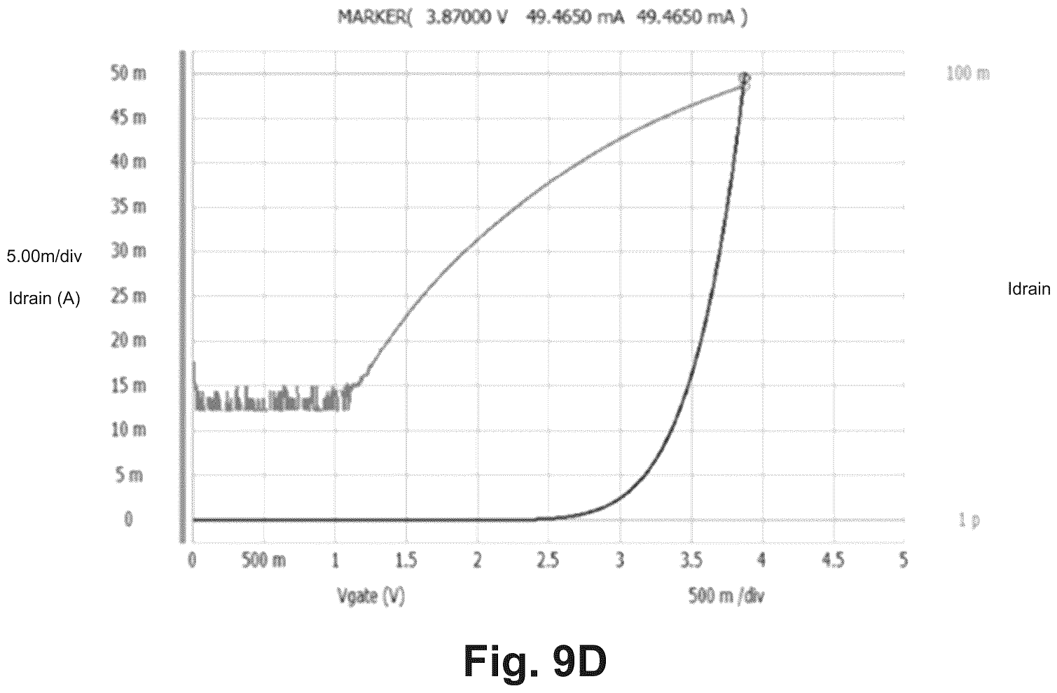

Before the tests, multiple SiC MOSFET switches went through accelerated life cycles in an in-house aging station. Two sets of samples were selected for initial testing. The first set included two devices (Phase V upper switch and Phase W upper switch) on a Wolfspeed CCSO20M12CM2 sixpack for different R_{ds,on}, and two Wolfspeed C3M0075120D single modules for different Vₜₕ. The device curve tracing comparisons are shown in FIGS. 9A-D.

FIG. 9A illustrates results from an aging detector (combination of circuit 800 and functions of the controller 132 related to generating aging information) for a Phase V sixpack (aged), according to some aspects of the present disclosure. FIG. 9B illustrates results from an aging detector for a Phase W sixpack (new), according to some aspects of the present disclosure. FIG. 9C illustrates results from an aging detector for a single TO-247 (aged), according to some aspects of the present disclosure. FIG. 9D illustrates results from an aging detector for a single TO-247 (new) according to some aspects of the present disclosure.

As may be appreciated from FIGS. 9A and 9B, the difference in R_{ds,on} is approximately 7 mOhm (approximately 77 mOhm versus approximately 84 mOhm) for the given current condition. As may be appreciated from FIGS. 9C and 9D, the difference in Vₜₕ is approximately 0.45 V (approximately 3.85 V versus approximately 4.3 V). Before the detection tests, the aged device in the sixpack underwent approximately 10,000 powered thermal cycles at approximately 120° C., and the aged device TO-247 module underwent approximately 50,000 over-gate voltage cycles (approximately 20 V applied versus approximately 15 V rated) in a temperature range of approximately 50° C. to approximately 80° C.

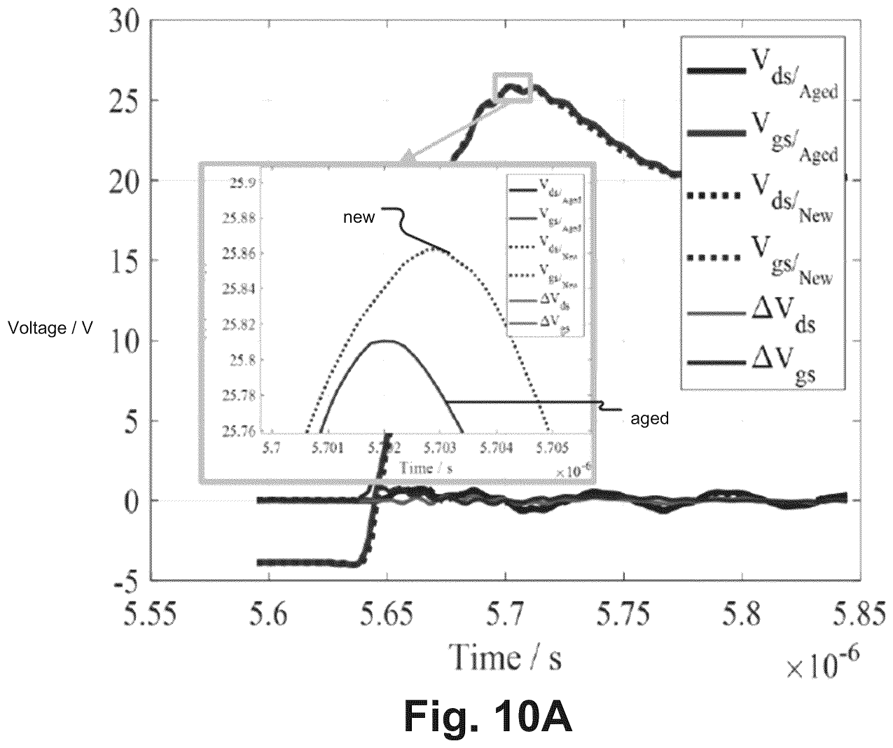

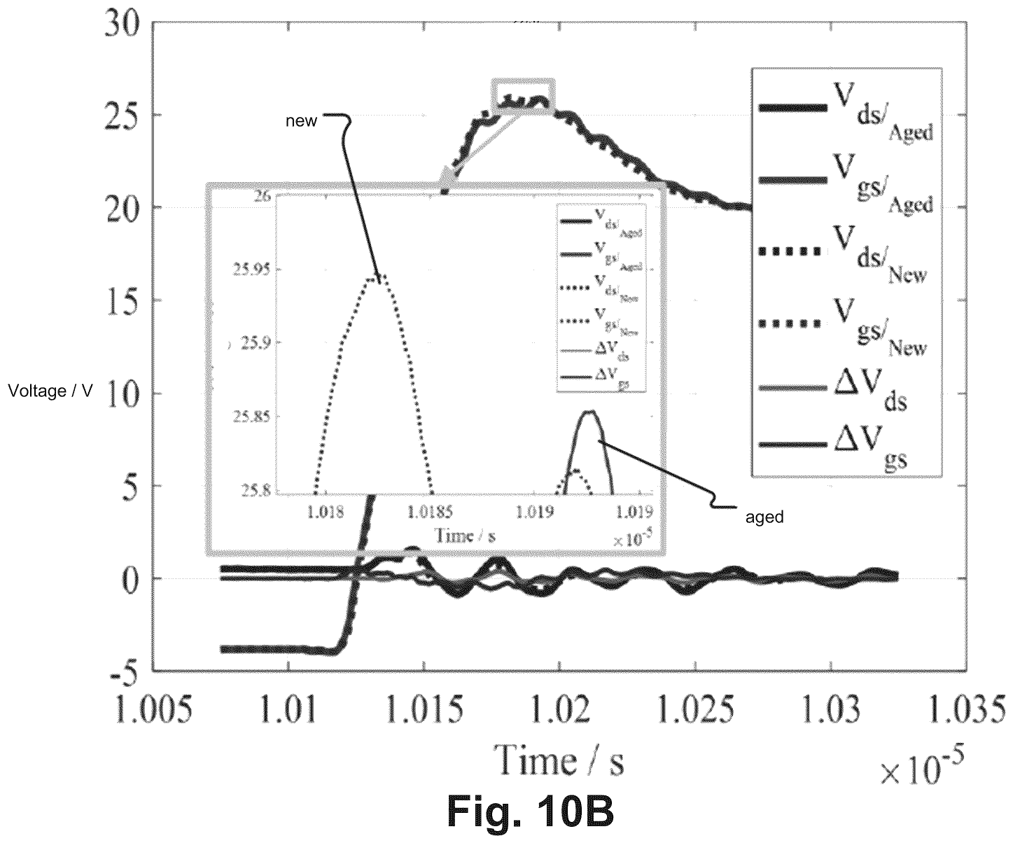

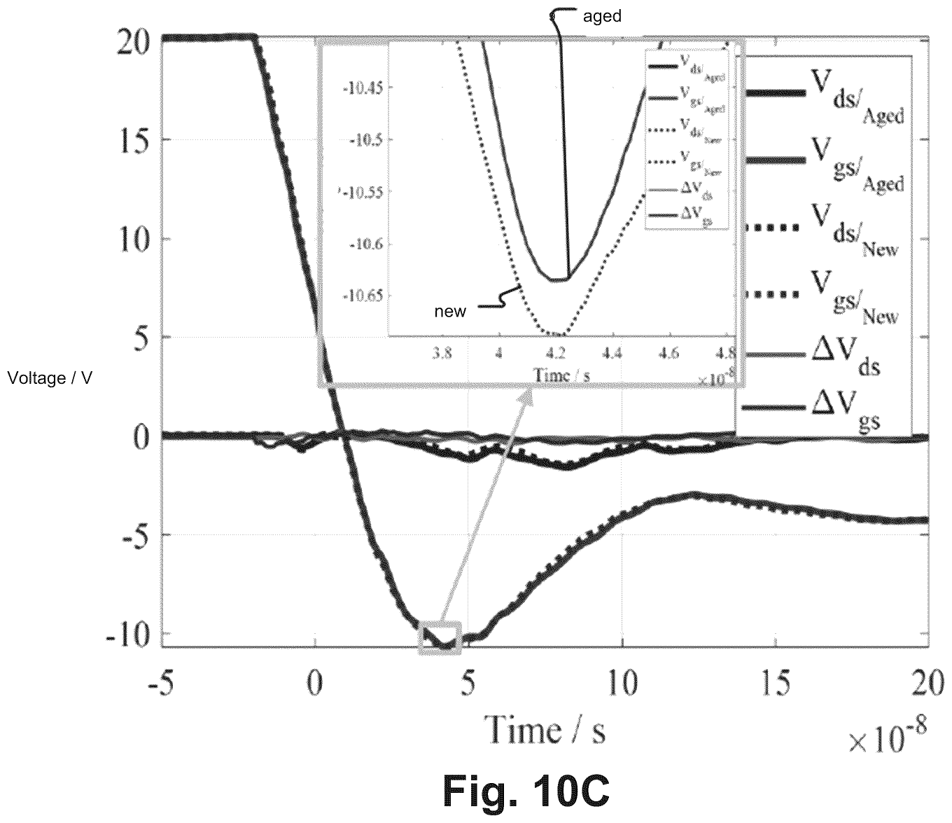

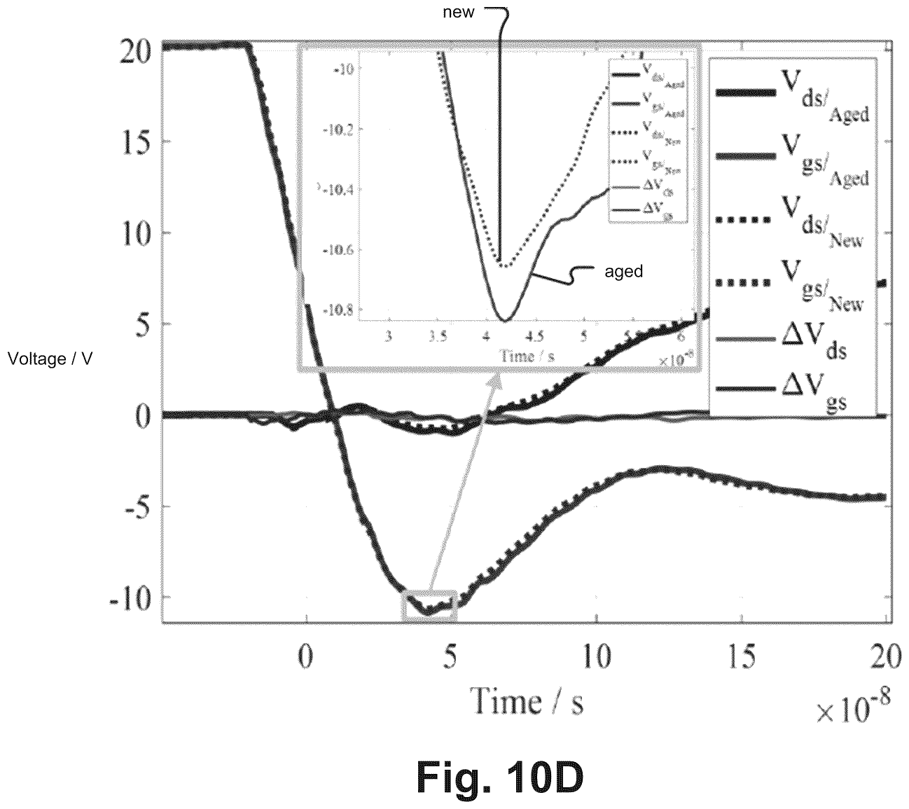

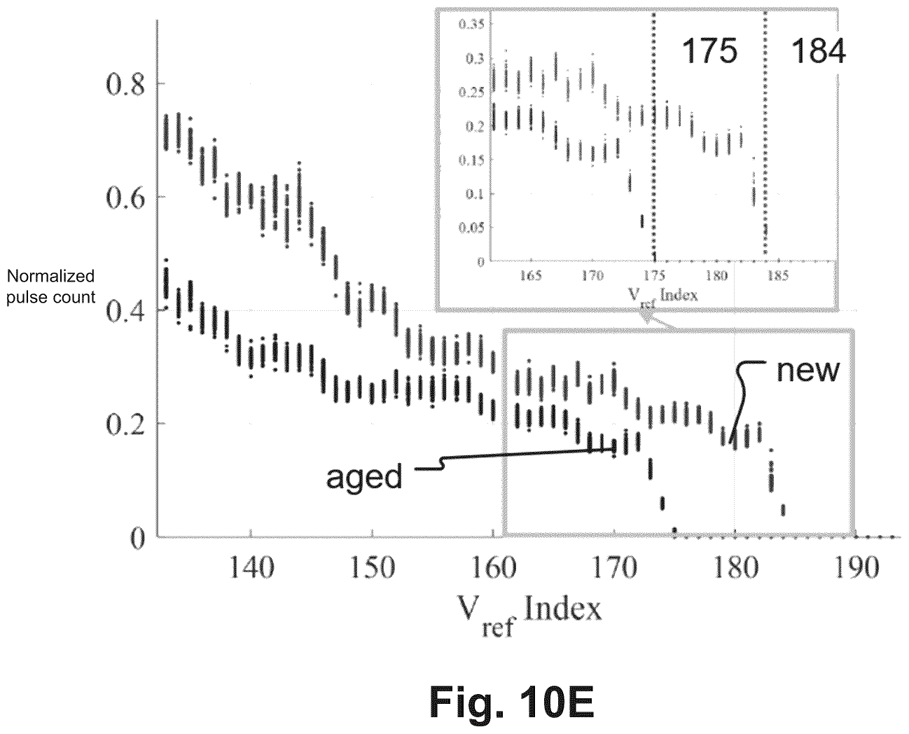

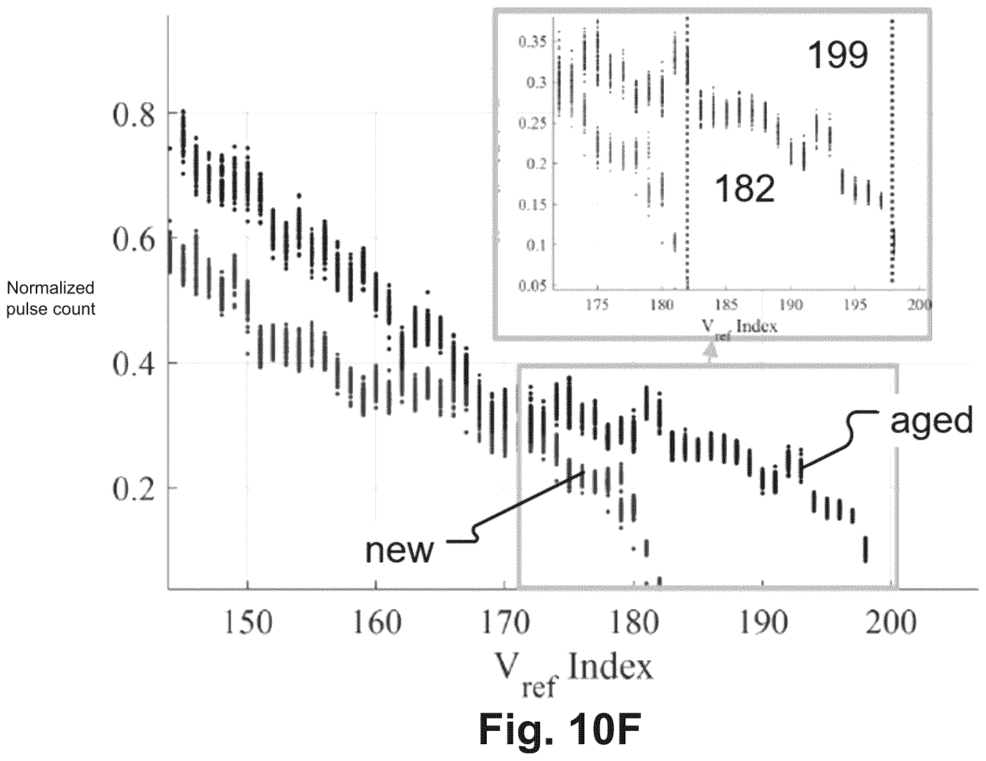

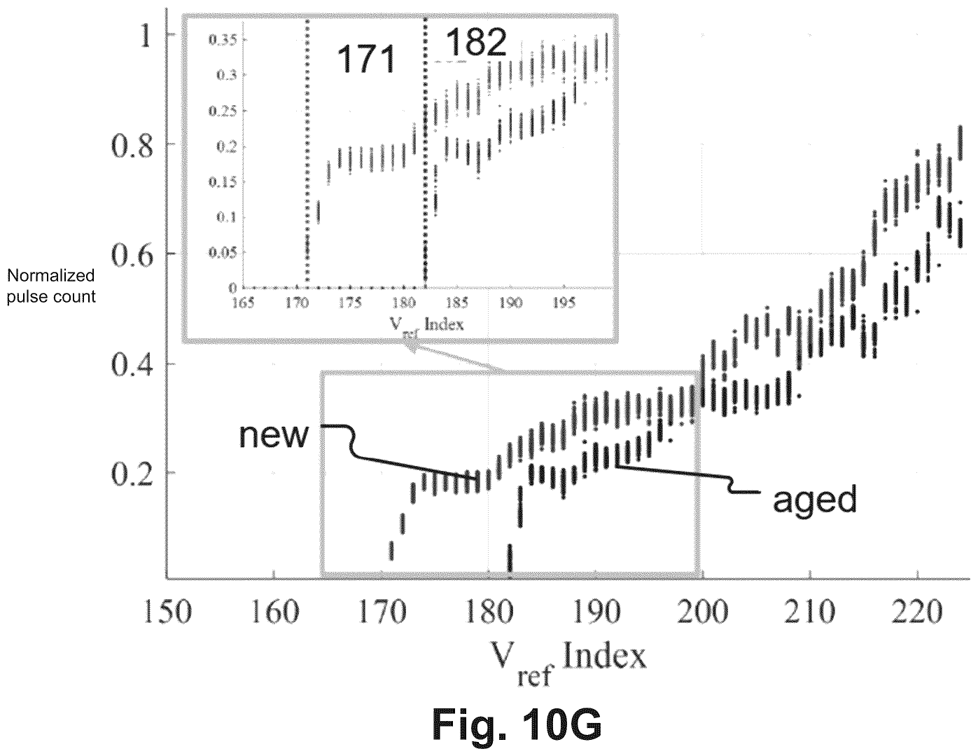

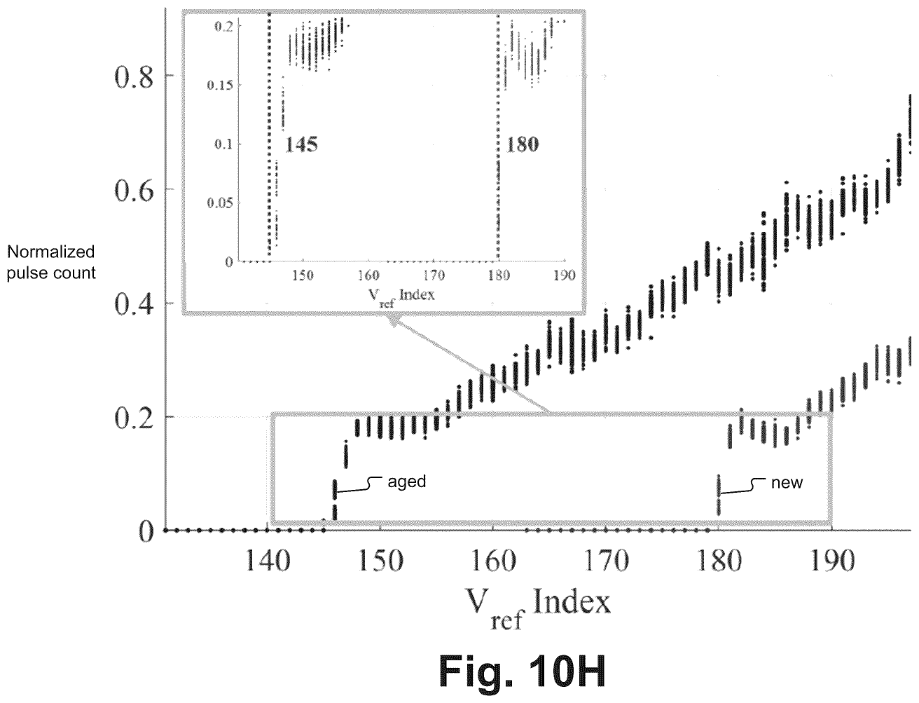

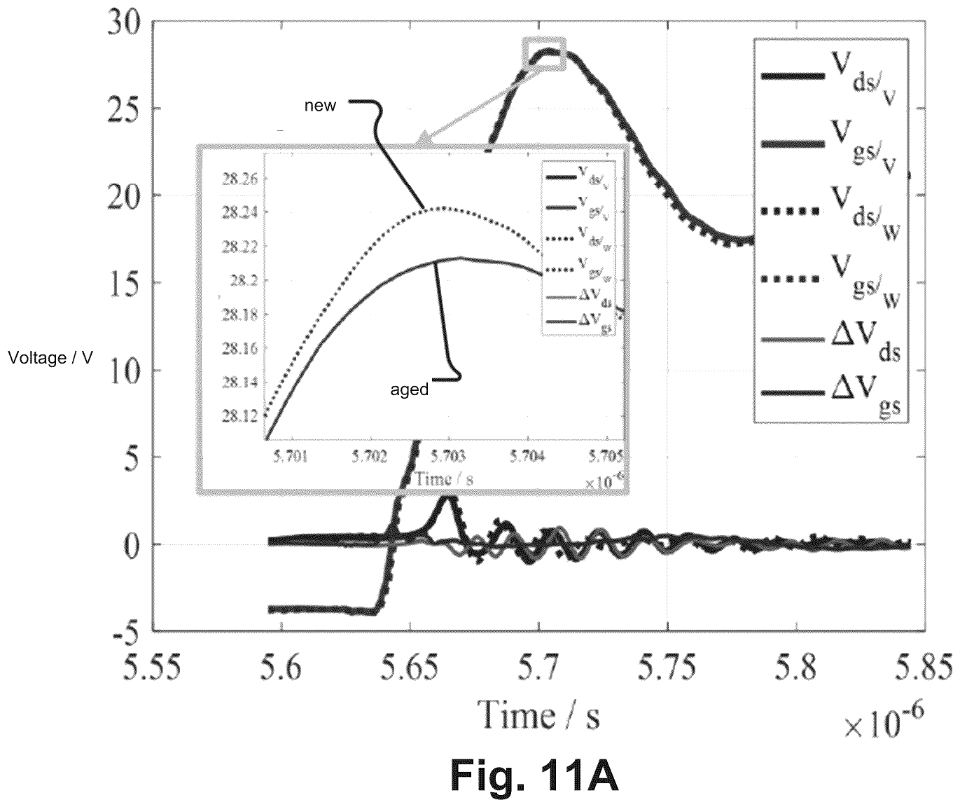

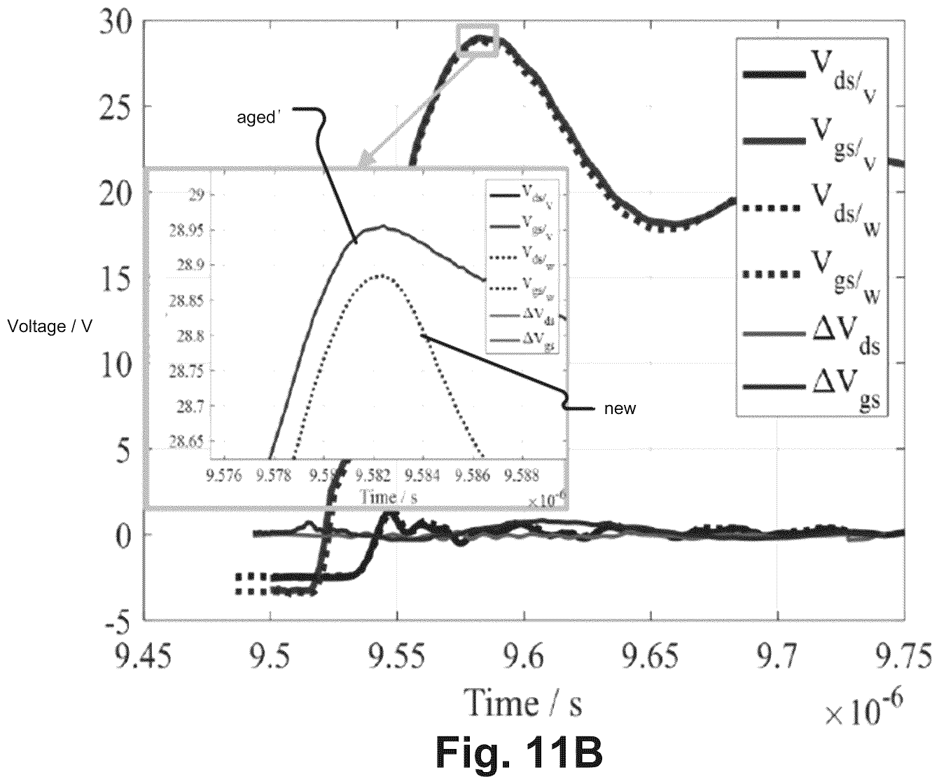

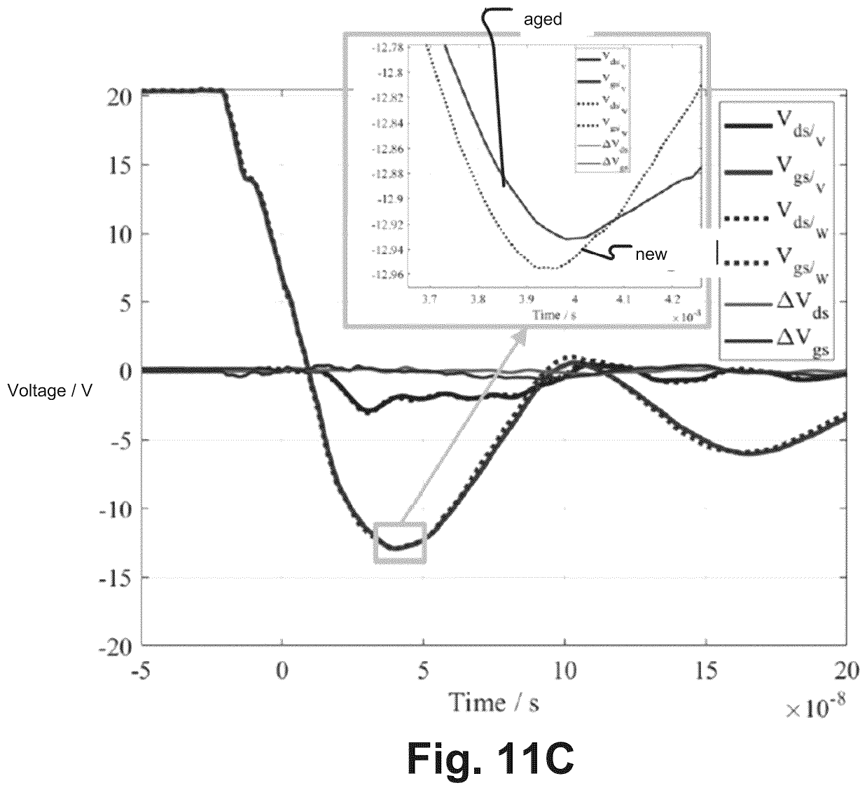

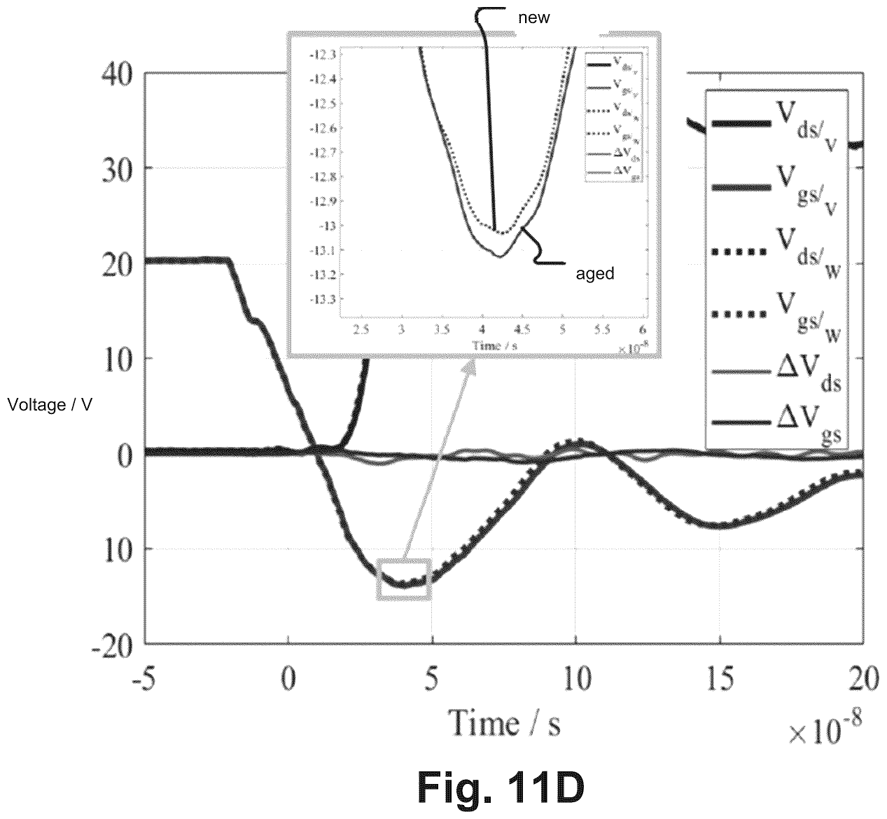

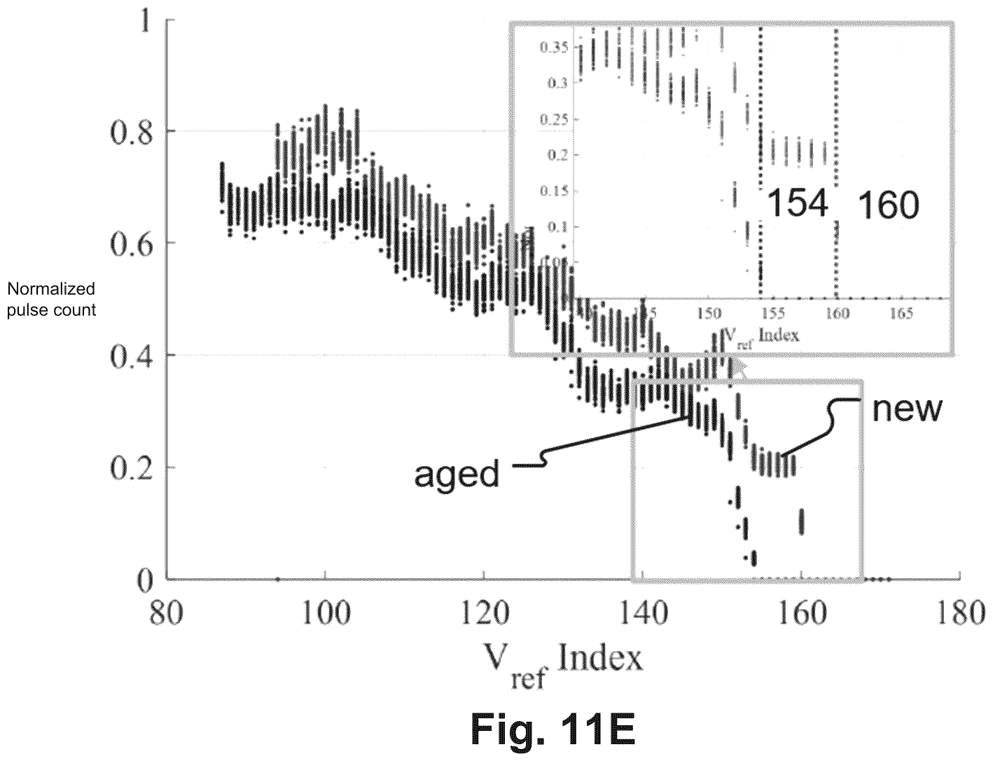

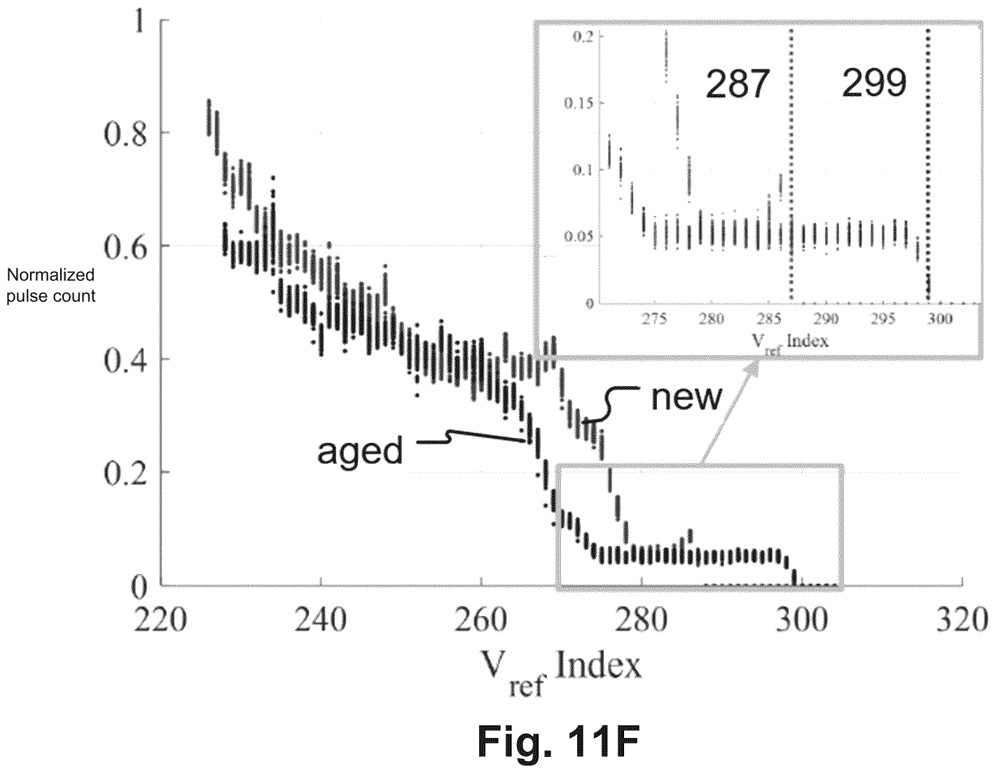

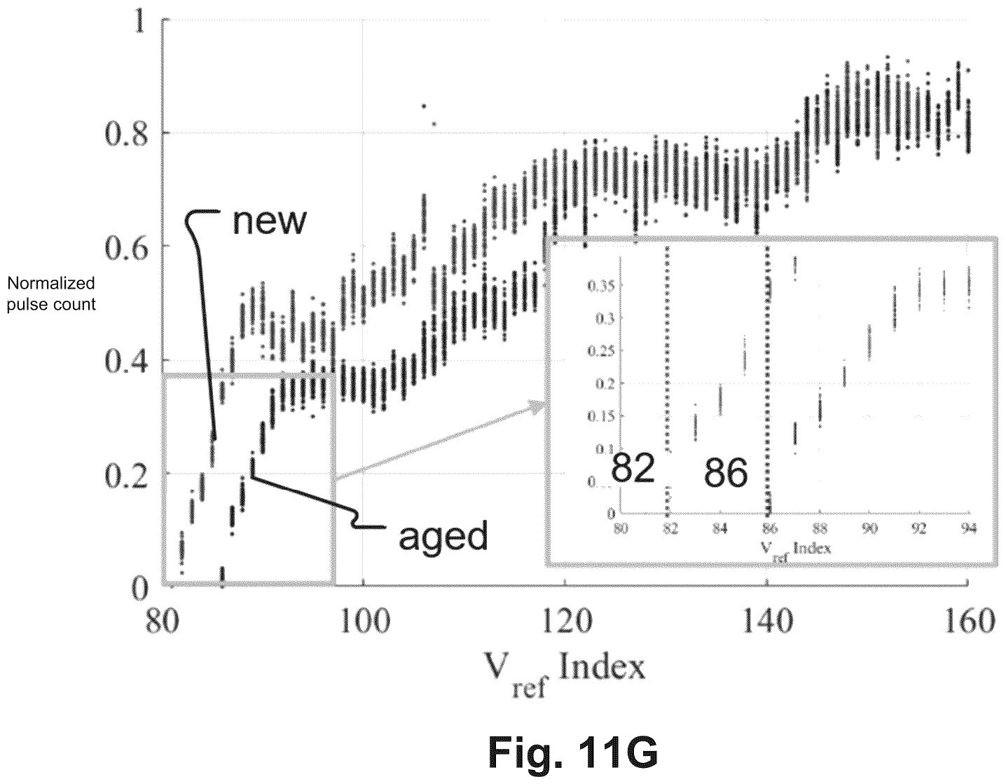

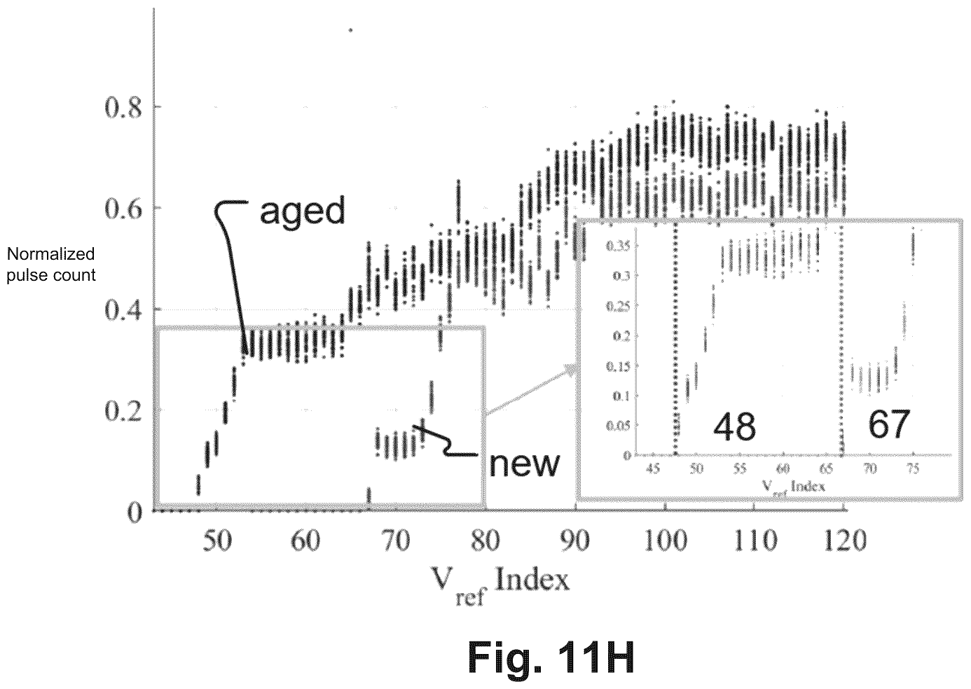

The test results for Vₜₕ change detection are shown in FIGS. 10A-10H. The test results for R_{ds,on} change detection are shown in FIGS. 11A-11H. In FIGS. 10A-D to 11A-D, the traces labeled “new” represent Vgs of the new device (power switch), and the traces labeled “aged” represent Vgs of the aged device (power switch). As may be appreciated, FIGS. 10A-10D and 11A-11D contain insets that focus on measurements for Vgs, and thus, the remaining lines for Vds and changes in Vds and Vgs are not necessarily distinguishable in the figures.

Specifically, FIGS. 10A-10D illustrate detection results for Vₜₕ change shown with scope measurements, according to some aspects of the present disclosure. FIGS. 10E-10H illustrates detection results for Vₜₕ change shown with pulses as generated by circuit 800 and counted by the controller 132, according to some aspects of the present disclosure. In more detail with reference to FIGS. 10A-10H and 10B, FIGS. 10A and 10E show results for the turn-on transient with zero DC bus voltage, FIGS. 10B and 10F show results for the turn-on transient with 30V DC bus voltage, FIGS. 10C and 10G show the turn-off transient with zero DC bus voltage, and FIGS. 10D and 10H show the turn-off transient with 30V DC bus voltage.

FIGS. 11A-11D illustrate detection results for R_{ds,on} change shown with scope measurements, according to some aspects of the present disclosure. FIGS. 11E-11H illustrate detection results for R_{ds,on} change shown with pulses as generated by circuit 800 and counted by the controller 132, according to some aspects of the present disclosure. In more detail with reference to FIGS. 11A-11H, FIGS. 11A and 11E show results for the turn-on transient with zero DC bus voltage, FIGS. 11B and 11F show results for the turn-on transient with 30V DC bus voltage, FIGS. 11C and 11G show the turn-off transient with zero DC bus voltage, and FIGS. 11D and 11H show the turn-off transient with 30V DC bus voltage.

The reference voltage Vref definition generated for the circuit 800 was approximately 5 mV per step. In order to cover a wide voltage range while maintaining the definition, multiple external reference voltages Vref for level shifting were used, of approximately 27.5 V, approximately −13.3 V, approximately 25.0 V, and approximately −11.5 V for six pack turn on, sixpack turn off, TO-247 turn on, and TO-247 turn off, respectively.

The V_{gs} peak value differences are indicated by the difference in pulse emerging/vanishing indices in FIGS. 10E-H and FIGS. 11E-H having patterns that generally match those from shown in FIGS. 10A-10D and 11A-D, respectively, thereby validating the aging detector of the present disclosure. As may be appreciated, one may run more tests on more aged and new devices to construct a database (e.g., a lookup table (LUT)) that matches measured Vₜₕ and R_{ds,on} values (e.g., scope measurements like in FIGS. 10A-D and FIGS. 11A-11D) to corresponding indexed pulse counts (e.g., like the graphs in FIGS. 10E-10H and FIGS. 11E-H). The controller 132 may store or have access to this database for the sake of determining aging information based on output of the circuit 800. That is, the number of pulses counted by controller 132 over time is indicative of Vₜₕ and R_{ds,on}(or change in Vₜₕ and R_{ds,on}) for a power switch in a power module 108, and the controller 132 may determine values for Vₜₕ and/or R_{ds,on}(i.e., the aging information) for the power switch based on the counted number of pulses. The controller 132 may then send the aging information, with or without other SOH information, to RF circuit 124 for wireless transmission to an interested party, such as an operator of the power module 104, through RF circuit 120. The interested party can then assess the SOH of the power switch and perform maintenance operations or adjust operating parameters of the power module 104 to decrease the chance of complete failure of the power switch (e.g., by using the feedback aging information to adjust the PWM signal generated by the signal generator 122).

In view of the description of the figures herein, at least one embodiment of the present disclosure is directed to a power module 104 that comprises a power circuit 128. The power circuit 128 may comprise one or more power switches (e.g., devices 1 to 4 embodied as switches Sla to S2b) configured to provide power to a load 108. The power module 104 may include a first wireless interface, such as RF circuit 124, configured to receive a first wireless signal. As described herein, the first wireless signal may be a PWM signal generated by signal generator 122 and sent to RF circuit 124 by RF circuit 120. In some examples, the first wireless interface comprises a Wi-Fi communication interface and the RF circuits 120 and 124 communicate with Wi-Fi signals. In other examples, the first wireless interface comprises an Ultra-Wideband (UWB) communication interface, and the RF circuits 120 and 124 communicate with UWB signals. As may be appreciated, the latency achieved with UWB communication is lower than the latency achieved with Wi-Fi communication.

The power module 104 may further include a controller 132 configured to generate a drive signal based on the first wireless signal and drive the one or more power switches with the drive signal to provide the power to the load 108. The drive signal may be a PWM signal output by a gate driver of the controller 132 that has a frequency, amplitude, and duty ratio for driving the one or more power switches. For example, the controller 132 may receive a PWM signal that already has the intended frequency and duty ratio from the RF circuit 124 (with that PWM signal being based on the first wireless signal), and the gate driver may amplify that signal to output the drive signal. In other examples, the controller 132 receives a signal from the RF circuit 124 that contains information about the frequency, amplitude, and duty ratio intended for the drive signal, extracts the information and, with the aid of the gate driver, generates the drive signal to have the intended frequency, amplitude, and duty ratio.

The power module 104 may further comprise a second wireless interface, such as an inductive power transfer (IPT) circuit that includes the WPT Rx circuit 116, which is configured to receive and convert a second wireless signal into power for elements of the power module 104, such as the controller 132 and the first wireless interface. The second wireless signal may be received from an external transmitter, such as the WPT Tx circuit 112. In some examples, the power module 104 also comprises a SOH circuit 136 coupled to the power circuit 128 and the controller 136. As described with reference to FIGS. 8A to 11H, the controller 132 is configured to generate SOH information about the power circuit 128 based on output of the SOH circuit 136. The SOH circuit 136 may comprise circuit 800 described above with reference to FIGS. 8A and 8B. As shown in FIG. 8A, the circuit 800 comprises a comparator circuit configured to compare an aging signal to a reference signal Vref and generate a pulse when the reference signal Vref reaches a peak of the aging signal. As may be appreciated, the aging signal is derived from a gate-source voltage Vgs of the one or more power switches (e.g., a voltage divided version of Vgs), and the counted number of pulses over time is indicative of at least one of an on-state resistance of the one or more power switches or a threshold voltage of the one or more power switches. Thus, the SOH information may comprise aging information about the one or more power switches, such as estimated values for Vₜₕ and R_{ds,on} and/or estimated changes to Vₜₕ and R_{ds,on} compared to a previous point in time. As described above with reference to FIGS. 8A to 11H, the controller 132 is configured to count a number of pulses output by the circuit 800 (e.g., by the comparator circuit) and determine the aging information based on the counted number of pulses. The determination may involve accessing a database of that matches previously measured values of Vₜₕ and R_{ds,on} and/or previously measured changes to Vₜₕ and R_{ds,on} for the one or more power switches to an indexed counted number of pulses previously known to be associated with the measured values of Vₜₕ and R_{ds,on} and/or measured changes to Vₜₕ and R_{ds,on}. The database may be constructed prior to operation of the power module 104 by running tests to obtain measured results and pulse count results that correspond to the measured results as described above with reference to FIGS. 10A-11H.

In some embodiments, the first wireless interface (RF circuit 124) is configured to wirelessly transmit the SOH information to an external device, such as the RF circuit 120. Notably, the first wireless interface may also be configured to wirelessly transmit feedback from the load 108 to the same or different external device. The feedback may be included with the SOH information or be separate from the SOH information. The feedback may comprise information indicative of a voltage and/or a current being consumed by or detected at the load 108 and/or other information deemed useful for adjusting the drive signal driving the one or more power switches to better match the intended operating parameters (voltage and/or current) of the load 108. In some examples, the feedback is transmitted wirelessly back to the RF circuit 120 where the signal generator 122 then generates or adjusts its signal based on the feedback for transmission back to the power module 104 causing the controller 132 adjusts the drive signal driving the power switches to account for the feedback.

As described herein, the one or more power switches may comprise at least two power switches in a half-bridge configuration, shown in FIG. 2. In some examples, the power module 104 further comprises a power converter circuit, such as DC-DC converter(s) 140, which is configured to at least one of step-up or step-down the power converted by the second wireless interface 116.

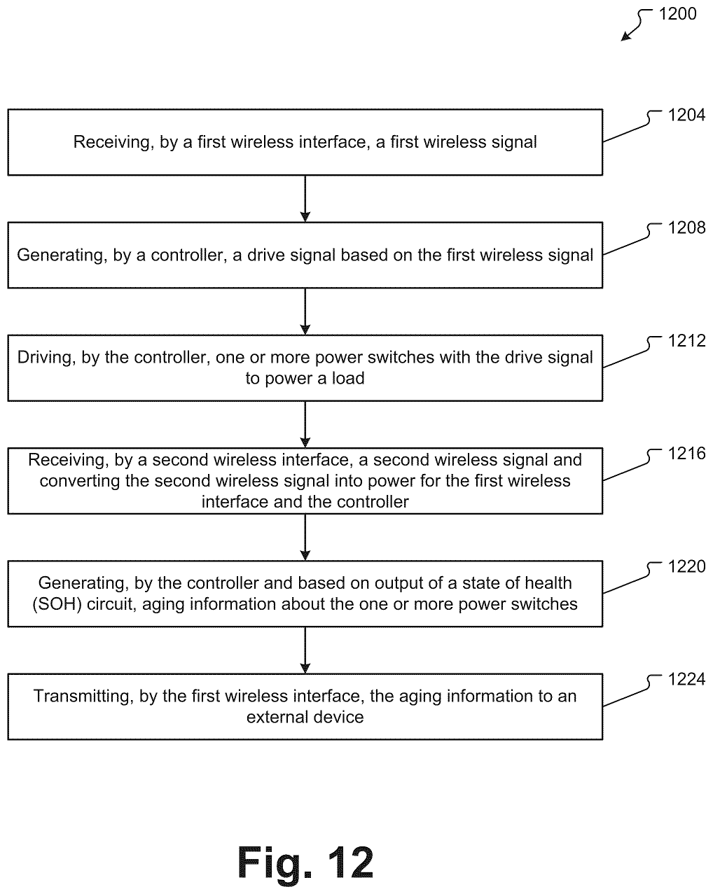

FIG. 12 depicts a method 1200 for operating a power module according to at least one embodiment of the present disclosure.

The method 1200 (and/or one or more operations thereof) may be carried out or otherwise performed, for example, by one or more components described herein with reference to FIGS. 1-11B.

Operation 1204 includes receiving, by a first wireless interface, a first wireless signal. Here, the first wireless interface may correspond to RF circuit 124 of the power module 104, and the first wireless signal may correspond to a PWM signal or other signal with PWM information (frequency and duty ratio) for generating a PWM signal, as generated by signal generator 122.

Operation 1208 includes generating, by a controller, such as controller 132, a drive signal based on the first wireless signal. The drive signal may correspond to a PWM signal generated by the controller 132 to have a frequency, duty ratio, and/or amplitude for driving power switches of a power circuit 128 to power a load 108. The PWM signal output by a signal generating part of the controller 132 may be amplified, for example, by a gate driver to result in the drive signal.

Operation 1212 includes driving, by the controller 132, one or more power switches with the drive signal to power a load 108. For example, the drive signal drives switches S1a to S2b in FIG. 2 to cause the power module 104 to convert Vin into Vout. However, the drive signal may drive power switches in other configurations depending on the application.

Operation 1216 includes receiving, by a second wireless interface, a second wireless signal and converting the second wireless signal into power for the first wireless interface and the controller 132. The second wireless interface may correspond to or include part of an IPT circuit, such as WPT Rx circuit 116. As described herein, the WPT Rx circuit 116 converts wireless signals from WPT Tx circuit 112 into power using inductive power transfer principles.

Operation 1220 includes generating, by the controller 132 and based on output of a state of health (SOH) circuit 136, aging information about the one or more power switches. As described above, the aging information may comprise estimated Vₜₕ and R_{ds,on} for a power switch under consideration and/or estimated changes to Vₜₕ and R_{ds,on} for the power switch under consideration, and the aging information may be generated in accordance with the discussion of FIGS. 8A to 11H.

In operation 1224, the method includes transmitting, by the first wireless interface, the aging information to an external device. Here, the external device may comprise the RF circuit 120 or a device connected to the RF circuit 120, such as a user interface with a display that enables an operator of the power module 104 to see a visual indication of the aging information. In some examples, the aging information may trigger a notice to inform the operator that the power switch is at risk of failure or that the power switch is healthy and may continue to operate normally. In some examples, the notice causes the operator to take one or more actions, such as performing or scheduling maintenance for the power module. In other examples, the system takes automatic action, for example, by instructing the signal generator 122 to generate a signal that changes the drive signal generated by the controller 132 in a manner that reduces the risk of failure of the power switch.

Although not explicitly shown in the method 1200, the method may further comprise the power module 104 sending feedback about the load 108 to the RF circuit 120 to in turn cause the signal generator 122 to adjust its generated signal and send the adjusted signal back to the power module 104 so that the drive signal is adjusted appropriately.

The present disclosure encompasses embodiments of the method 1200 that comprise more or fewer steps than those described above, and/or one or more steps that are different than the steps described above.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations may be combined in alternate aspects, embodiments, or configurations other than those discussed above. It is to be appreciated that any feature described herein can be claimed in combination with any other feature(s) as described herein, regardless of whether the features come from the same described embodiment. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein.

Thus, the following claims are hereby incorporated into this Detailed Description, with each claim standing on its own as a separate aspect, embodiment, or configuration.

Aspects of the present disclosure may be configured as follows:

(1) A power module, comprising:
a power circuit comprising one or more power switches configured to provide power to a load;
a first wireless interface configured to receive a first wireless signal;
a controller configured to:
   generate a drive signal based on the first wireless signal; and
   drive the one or more power switches with the drive signal to provide the power to the load; and
a second wireless interface configured to receive and convert a second wireless signal into power for the controller and the first wireless interface.

(2) The power module of (1), further comprising:
a state of health (SOH) circuit coupled to the power circuit, wherein the controller is configured to generate SOH information about the power circuit based on output of the SOH circuit.

(3) The power module of one or more of (1) to (2), wherein the first wireless interface is configured to wirelessly transmit the SOH information to an external device.

(4) The power module of one or more of (1) to (3), wherein the SOH information comprises aging information about the one or more power switches.

(5) The power module of one or more of (1) to (4), wherein the SOH circuit comprises a comparator circuit configured to compare an aging signal to a reference signal and generate a pulse when the reference signal reaches a peak of the aging signal.

(6) The power module of one or more of (1) to (5), wherein the controller is configured to count a number of pulses output by the comparator circuit and determine aging information based on the counted number of pulses.

(7) The power module of one or more of (1) to (6), wherein the aging signal is derived from a gate-source voltage of the one or more power switches, and wherein the counted number of pulses over time is indicative of at least one of an on-state resistance of the one or more power switches or a threshold voltage of the one or more power switches.

(8) The power module of one or more of (1) to (7), wherein the first wireless interface is configured to wirelessly transmit feedback from the load to an external device.

(9) The power module of one or more of (1) to (8), wherein the first wireless signal received by the first wireless interface is generated based on the feedback.

(10) The power module of one or more of (1) to (9), wherein the one or more power switches comprise at least two power switches in a half-bridge configuration.

(11) The power module of one or more of (1) to (10), wherein the first wireless interface comprises a Wi-Fi communication interface.

(12) The power module of one or more of (1) to (11), wherein the first wireless interface comprises an Ultra-Wideband (UWB) communication interface.

(13) The power module of one or more of (1) to (12), further comprising:
a power converter circuit configured to at least one of step-up or step-down the power converted by the second wireless interface.

(14) The power module of one or more of (1) to (13), wherein the first wireless signal received by the first wireless interface and the drive signal are pulse-width modulated signals.

(15) A system for providing power, comprising:
a first transmitter configured to wirelessly transmit a first pulse-width modulated (PWM) signal; and
a power module comprising:
   a power circuit comprising one or more power switches configured to provide power to a load;
   a first wireless interface configured to receive the first PWM signal from the first transmitter;
   a controller configured to:
      generate a second PWM signal based on the first PWM signal; and
      drive the one or more power switches with the second PWM signal to provide the power to the load; and
   an inductive power transfer (IPT) circuit configured to receive and convert a wireless signal into power for the controller and the first wireless interface.

(16) The system of (15), further comprising:
a second transmitter configured to wirelessly transmit the wireless signal to the IPT circuit.

(17) The system of one or more of (15) to (16), wherein the first wireless interface is configured to wirelessly transmit feedback from the load to the first transmitter.

(18) The system of one or more of (15) to (17), wherein the transmitter is configured to generate the first PWM signal based on the feedback.

(19) The system of one or more of (15) to (18), wherein the power module further comprises:
a state of health (SOH) circuit coupled to the power circuit, wherein the controller is configured to generate aging information about the power circuit based on output of the SOH circuit.

(20) A method for providing power, comprising:
receiving, by a first wireless interface, a first wireless signal;
generating, by a controller, a drive signal based on the first wireless signal;
driving, by the controller, one or more power switches with the drive signal to power a load;
receiving, by a second wireless interface, a second wireless signal and converting the second wireless signal into power for the first wireless interface and the controller;
generating, by the controller and based on output of a state of health (SOH) circuit, aging information about the one or more power switches; and
transmitting, by the first wireless interface, the aging information to an external device.

What is claimed is:

1. A power module, comprising:
a power circuit comprising one or more power switches configured to provide power to a load;
a first wireless interface configured to receive a first wireless signal;
a controller configured to:
generate a drive signal based on the first wireless signal; and
drive the one or more power switches with the drive signal to provide the power to the load; and
a second wireless interface configured to receive and convert a second wireless signal into power for the controller and the first wireless interface.

2. The power module of claim 1, further comprising:
a state of health (SOH) circuit coupled to the power circuit, wherein the controller is configured to generate SOH information about the power circuit based on output of the SOH circuit.

3. The power module of claim 2, wherein the first wireless interface is configured to wirelessly transmit the SOH information to an external device.

4. The power module of claim 2, wherein the SOH information comprises aging information about the one or more power switches.

5. The power module of claim 4, wherein the SOH circuit comprises a comparator circuit configured to compare an aging signal to a reference signal and generate a pulse when the reference signal reaches a peak of the aging signal.

6. The power module of claim 5, wherein the controller is configured to count a number of pulses output by the comparator circuit and determine aging information based on the counted number of pulses.

7. The power module of claim 6, wherein the aging signal is derived from a gate-source voltage of the one or more power switches, and wherein the counted number of pulses over time is indicative of at least one of an on-state resistance of the one or more power switches or a threshold voltage of the one or more power switches.

8. The power module of claim 1, wherein the first wireless interface is configured to wirelessly transmit feedback from the load to an external device.

9. The power module of claim 8, wherein the first wireless signal received by the first wireless interface is generated based on the feedback.

10. The power module of claim 1, wherein the one or more power switches comprise at least two power switches in a half-bridge configuration.

11. The power module of claim 1, wherein the first wireless interface comprises a Wi-Fi communication interface.

12. The power module of claim 1, wherein the first wireless interface comprises an Ultra-Wideband (UWB) communication interface.

13. The power module of claim 1, further comprising:
a power converter circuit configured to at least one of step-up or step-down the power converted by the second wireless interface.

14. The power module of claim 1, wherein the first wireless signal received by the first wireless interface and the drive signal are pulse-width modulated signals.

15. A system for providing power, comprising:
a first transmitter configured to wirelessly transmit a first pulse-width modulated (PWM) signal; and
a power module comprising:
a power circuit comprising one or more power switches configured to provide power to a load;
a first wireless interface configured to receive the first PWM signal from the first transmitter;
a controller configured to:
generate a second PWM signal based on the first PWM signal; and
drive the one or more power switches with the second PWM signal to provide the power to the load; and
an inductive power transfer (IPT) circuit configured to receive and convert a wireless signal into power for the controller and the first wireless interface.

16. The system of claim 15, further comprising:
a second transmitter configured to wirelessly transmit the wireless signal to the IPT circuit.

17. The system of claim 15, wherein the first wireless interface is configured to wirelessly transmit feedback from the load to the first transmitter.

18. The system of claim 17, wherein the transmitter is configured to generate the first PWM signal based on the feedback.

19. The system of claim 15, wherein the power module further comprises:
a state of health (SOH) circuit coupled to the power circuit, wherein the controller is configured to generate aging information about the power circuit based on output of the SOH circuit.

20. A method for providing power, comprising:
receiving, by a first wireless interface, a first wireless signal;
generating, by a controller, a drive signal based on the first wireless signal;
driving, by the controller, one or more power switches with the drive signal to power a load;
receiving, by a second wireless interface, a second wireless signal and converting the second wireless signal into power for the first wireless interface and the controller;
generating, by the controller and based on output of a state of health (SOH) circuit, aging information about the one or more power switches; and
transmitting, by the first wireless interface, the aging information to an external device.
